(19) United States
(12) Patent Application Publication
(10) Pub. No.: US 2015/0037941 A1
(43) Pub. Date: Feb. 5, 2015

(54) FINFET CONTACTING A CONDUCTIVE STRAP STRUCTURE OF A DRAM

(71) Applicant: International Business Machines Corporation, Armonk, NY (US)

(72) Inventors: Josephine B. Chang, Mahopac, NY (US); Babar A. Khan, Ossining, NY (US); Paul C. Parries, Wappingers Falls, NY (US); Xinhui Wang, Poughkeepsie, NY (US)

(21) Appl. No.: 14/516,721

(22) Filed: Oct. 17, 2014

Related U.S. Application Data
(62) Division of application No. 13/484,657, filed on May 31, 2012.

(51) Int. Cl. H01L 27/108; H01L 27/12

(52) U.S. Cl. CPC H01L 27/10844; H01L 27/1207; H01L 27/1211
USPC 438/152

(57) ABSTRACT

A conductive strap structure in lateral contact with a top semiconductor layer is formed on an inner electrode of a deep trench capacitor. A cavity overlying the conductive strap structure is filled with a dielectric material to form a dielectric capacitor cap having a top surface that is coplanar with a topmost surface of an upper pad layer. A portion of the upper pad layer is removed to define a line cavity. A fin-defining spacer comprising a material different from the material of the dielectric capacitor cap and the upper pad layer is formed around the line cavity by deposition of a conformal layer and an anisotropic etch. The upper pad layer is removed, and the fin-defining spacer is employed as an etch mask to form a semiconductor fin that laterally contacts the conductive strap structure. An access finFET is formed employing two parallel portions of the semiconductor fin.

### BACKGROUND

The present disclosure relates to a semiconductor structure, and particularly to a dynamic random access memory (DRAM) cell including a finFET access transistor and a method of manufacturing the same.

Deep trench capacitors are used in a variety of semiconductor chips for high areal capacitance and low device leakage. Typically, a deep trench capacitor provides a capacitance in the range from 4 fF (femto-Farad) to 120 fF. A deep trench capacitor may be employed as a charge storage unit in a dynamic random access memory (DRAM), which may be provided as a stand-alone semiconductor chip, or may be embedded in a system-on-chip (SoC) semiconductor chip. A deep trench capacitor may also be employed in a variety of circuit applications such as a charge pump or a capacitive analog component in a radio-frequency (RF) circuit.

As dimensions of semiconductor devices scale, providing a robust low resistance path for electrical conduction between an inner electrode of a transistor and the source of an access transistor becomes a challenge because available area for forming a conductive strap structure decreases. However, because the read time and the write time of a DRAM cell is proportional to the product of the capacitance of a capacitor in the DRAM cell and the resistance of an electrically conductive path connected to the capacitor, a low resistance conductive path between the capacitor and the access transistor is required in order to reduce the read time and the write time of the DRAM cell.

### BRIEF SUMMARY

A conductive strap structure in lateral contact with a top semiconductor layer is formed on an inner electrode of a deep trench capacitor. A cavity overlying the conductive strap structure is filled with a dielectric material to form a dielectric capacitor cap having a top surface that is coplanar with a topmost surface of an upper pad layer. A portion of the upper pad layer is removed to define a line cavity. A fin-defining spacer comprising a material different from the material of the dielectric capacitor cap and the upper pad layer is formed around the line cavity by deposition of a conformal layer and an anisotropic etch. The upper pad layer is removed, and the fin-defining spacer is employed as an etch mask to form a semiconductor fin that laterally contacts the conductive strap structure. An access finFET is formed employing two parallel portions of the semiconductor fin.

According to an aspect of the present disclosure, a semiconductor structure includes a trench capacitor embedded in a substrate and including an inner electrode, a node dielectric, and an outer electrode. The semiconductor structure include further includes a conductive strap structure that is in contact with, and overlies, the inner electrode. In addition, the semiconductor structure includes a semiconductor fin, which includes a pair of channel regions having parallel sidewalls. A proximal sidewall of the conductive strap structure having a least lateral offset from the pair of channel regions among sidewalls of the conductive strap structure is in contact with the semiconductor fin.

According to another aspect of the present disclosure, a method of forming a semiconductor structure is provided. At least one pad layer is formed over a semiconductor-on-insulator (SOT) substrate. A trench capacitor including an inner electrode, a node dielectric, and an outer electrode in the SOI substrate is subsequently formed. A dielectric capacitor cap is formed over the inner electrode. A trough is formed in one of the at least one pad layer. The trough overlies a portion of a top semiconductor layer of the SOT substrate and a sidewall of the dielectric capacitor cap is physically exposed within the trough. A fin-defining spacer is formed on sidewalls of the one of the at least one pad layer and the sidewall of the dielectric capacitor cap within the trough. Then, a semiconductor fin is formed by transferring a pattern of the fin-defining spacer into the top semiconductor layer.

### BRIEF DESCRIPTION OF SEVERAL VIEWS OF THE DRAWINGS

FIG. 1A is a top-down view of an exemplary semiconductor structure after formation of a deep trench through a semiconductor-on-insulator (SOI) substrate according to an embodiment of the present disclosure.

FIG. 1B is a vertical cross-sectional view of the exemplary semiconductor structure along the vertical plane B-B′ of FIG. 1A.

FIG. 2A is a top-down view of the exemplary semiconductor structure after formation of a node dielectric layer and an inner electrode layer in the deep trench according to an embodiment of the present disclosure.

FIG. 2B is a vertical cross-sectional view of the exemplary semiconductor structure along the vertical plane B-B′ of FIG. 2A.

FIG. 3A is a top-down view of the exemplary semiconductor structure after recessing the inner electrode layer and removal of exposed portions of the node dielectric layer according to an embodiment of the present disclosure.

FIG. 3B is a vertical cross-sectional view of the exemplary semiconductor structure along the vertical plane B-B′ of FIG. 3A.

FIG. 4A is a top-down view of the exemplary semiconductor structure after formation of conductive strap structures by planarization according to an embodiment of the present disclosure.

FIG. 4B is a vertical cross-sectional view of the exemplary semiconductor structure along the vertical plane B-B′ of FIG. 4A.

FIG. 5A is a top-down view of the exemplary semiconductor structure after first recessing of the conductive strap structures according to an embodiment of the present disclosure.

FIG. 5B is a vertical cross-sectional view of the exemplary semiconductor structure along the vertical plane B-B′ of FIG. 5A.

FIG. 6A is a top-down view of the exemplary semiconductor structure after second recessing of the conductive strap structures according to an embodiment of the present disclosure.

FIG. 6B is a vertical cross-sectional view of the exemplary semiconductor structure along the vertical plane B-B′ of FIG. 6A.

FIG. 7A is a top-down view of the exemplary semiconductor structure after formation of dielectric capacitor caps according to an embodiment of the present disclosure.

FIG. 7B is a vertical cross-sectional view of the exemplary semiconductor structure along the vertical plane B-B′ of FIG. 7A.

FIG. 8A is a top-down view of the exemplary semiconductor structure after application and patterning of a photoresist layer to define an opening overlying a portion of a top semiconductor layer between a pair of dielectric capacitor caps according to an embodiment of the present disclosure.

FIG. 8B is a vertical cross-sectional view of the exemplary semiconductor structure along the vertical plane B-B′ of FIG. 8A.

FIG. 9A is a top-down view of the exemplary semiconductor structure after patterning of an upper pad layer employing the photoresist layer and subsequently removing the photoresist layer according to an embodiment of the present disclosure.

FIG. 9B is a vertical cross-sectional view of the exemplary semiconductor structure along the vertical plane B-B′ of FIG. 9A.

FIG. 10A is a top-down view of the exemplary semiconductor structure after formation of a fin-defining spacer according to an embodiment of the present disclosure.

FIG. 10B is a vertical cross-sectional view of the exemplary semiconductor structure along the vertical plane B-B′ of FIG. 10A.

FIG. 11A is a top-down view of the exemplary semiconductor structure after removal of the upper pad layer according to an embodiment of the present disclosure.

FIG. 11B is a vertical cross-sectional view of the exemplary semiconductor structure along the vertical plane B-B′ of FIG. 11A.

FIG. 12A is a top-down view of the exemplary semiconductor structure after patterning of a lower pad layer and the top semiconductor layer according to an embodiment of the present disclosure.

FIG. 12B is a vertical cross-sectional view of the exemplary semiconductor structure along the vertical plane B-B′ of FIG. 12A.

FIG. 13A is a top-down view of the exemplary semiconductor structure after removal of the fin-defining spacer and remaining portions of the lower pad layer according to an embodiment of the present disclosure.

FIG. 13B is a vertical cross-sectional view of the exemplary semiconductor structure along the vertical plane B-B′ of FIG. 13A.

FIG. 14A is a top-down view of the exemplary semiconductor structure after formation of gate dielectrics and gate electrodes according to an embodiment of the present disclosure.

FIG. 14B is a vertical cross-sectional view of the exemplary semiconductor structure along the vertical plane B-B′ of FIG. 14A.

FIG. 14C is a vertical cross-sectional view of the exemplary semiconductor structure along the vertical plane C-C′ of FIG. 14A.

FIG. 14D is a vertical cross-sectional view of the exemplary semiconductor structure along the vertical plane D-D′ of FIG. 14A.

FIG. 15A is a top-down view of the exemplary semiconductor structure after formation of gate spacers and source and drain regions according to an embodiment of the present disclosure.

FIG. 15B is a vertical cross-sectional view of the exemplary semiconductor structure along the vertical plane B-B′ of FIG. 15A.

FIG. 15C is a vertical cross-sectional view of the exemplary semiconductor structure along the vertical plane C-C′ of FIG. 15A.

FIG. 15D is a vertical cross-sectional view of the exemplary semiconductor structure along the vertical plane D-D′ of FIG. 15A.

FIG. 16A is a top-down view of the exemplary semiconductor structure after formation of a contact-level dielectric layer and various contact via structures according to an embodiment of the present disclosure. The contact-level dielectric layer is not shown in FIG. 16A for clarity.

FIG. 16B is a vertical cross-sectional view of the exemplary semiconductor structure along the vertical plane B-B′ of FIG. 16A.

FIG. 16C is a vertical cross-sectional view of the exemplary semiconductor structure along the vertical plane C-C′ of FIG. 16A.

FIG. 16D is a vertical cross-sectional view of the exemplary semiconductor structure along the vertical plane D-D′ of FIG. 16A.

FIG. 16E is a vertical cross-sectional view of a first variation of the exemplary semiconductor structure along a vertical plane corresponding to the vertical plane C-C′ of FIG. 17A.

FIG. 17A is a top-down view of a second variation of the exemplary semiconductor structure after formation of epitaxially expanded source regions and an epitaxially expanded drain region according to an embodiment of the present disclosure.

FIG. 17B is a vertical cross-sectional view of the second variation of the exemplary semiconductor structure along the vertical plane B-B′ of FIG. 17A.

FIG. 17C is a vertical cross-sectional view of the second variation of the exemplary semiconductor structure along the vertical plane C-C′ of FIG. 17A.

FIG. 17D is a vertical cross-sectional view of the second variation of the exemplary semiconductor structure along the vertical plane D-D′ of FIG. 17A.

### DETAILED DESCRIPTION

As stated above, the present disclosure relates to a semiconductor structure including a dynamic random access memory (DRAM) cell that includes a finFET access transistor and a method of manufacturing the same. Aspects of the present disclosure are now described in detail with accompanying figures. It is noted that like reference numerals refer to like elements across different embodiments. The drawings are not necessarily drawn to scale.

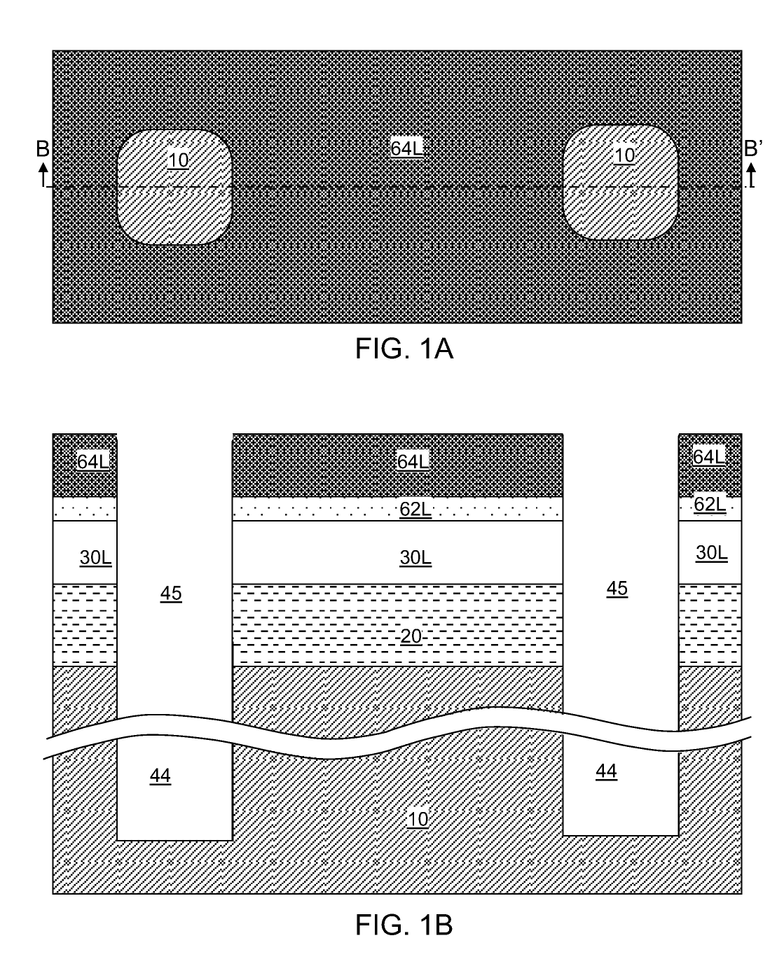

Referring to FIGS. 1A and 1B, an exemplary semiconductor structure according to a first embodiment of the present disclosure includes a semiconductor-on-insulator (SOI) substrate. The SOI substrate includes a stack, from bottom to top, of a bottom semiconductor layer 10, a buried insulator layer 20, and a top semiconductor layer 30L.

The bottom semiconductor layer 10 includes a semiconductor material. The buried insulator layer 20 includes a dielectric material such as silicon oxide, silicon nitride, a dielectric metal oxide, or a combination thereof. The top semiconductor layer 30L includes a semiconductor material, which can be the same as, or different from, the semiconductor material of the bottom semiconductor layer 10.

Each of the bottom semiconductor layer 10 and the top semiconductor layer 30L includes a semiconductor material independently selected from elemental semiconductor materials (e.g., silicon, germanium, carbon, or alloys thereof), III-V semiconductor materials, or II-VI semiconductor materials. Each semiconductor material for the bottom semiconductor layer 10 and the top semiconductor layer 30L can be independently single crystalline, polycrystalline, or amorphous. In one embodiment, the bottom semiconductor layer 10 and the top semiconductor layer 30L are single crystalline. In one embodiment, the bottom semiconductor layer 10 and the top semiconductor layer 30L include single crystalline silicon.

In one embodiment, the bottom semiconductor layer 10 can be doped with dopants of a first conductivity type. The first conductivity type can be p-type or n-type.

In one embodiment, the thickness of the top semiconductor layer 30L can be from 5 nm to 300 nm, the thickness of the buried insulator layer 20 can be from 50 nm to 1,000 nm, and the thickness of the bottom semiconductor layer 10 can be from 50 microns to 2 mm, although lesser and greater thicknesses can also be employed for each of these layers (10, 20, 30L).

At least one pad layer can be deposited on the SOI substrate (10, 20, 30L), for example, by chemical vapor deposition (CVD) or atomic layer deposition (ALD). The at least one pad layer can include one or more layers that can be employed as an etch mask for forming a deep trench 45 in the SOI substrate (10, 20, 30L). As used herein, a “deep trench” refers to a trench that extends from a topmost surface of a semiconductor-on-insulator (SOI) substrate through a top semiconductor layer and a buried insulator layer and partly into an underlying semiconductor layer. In one embodiment, each of the at least one pad layer can include a dielectric material such as silicon nitride, a dielectric metal nitride, a doped silicon undoped silicon oxide, or a dielectric metal oxide. The total thickness of the at least one pad layer can be from 100 nm to 2,000 nm, although lesser and greater thicknesses can also be employed.

In one embodiment, the at least one pad layer includes a stack of a lower pad layer 62L and an upper pad layer 64L. The lower pad layer 62L includes a first dielectric material, and the upper pad layer 64L includes a second dielectric material that is different from the first dielectric material. In one embodiment, the lower pad layer 62L can include a dielectric metal oxide, and the upper pad layer 64L can include silicon nitride. In one embodiment, the thickness of the lower pad layer 62L can be from 2 nm to 50 nm, and the thickness of the upper pad layer 64L can be from 40 nm to 360 nm, although lesser and greater thicknesses can also be employed for each of the lower pad layer 62L and the upper pad layer 64L.

A photoresist layer (not shown) can be applied over the at least one pad layer (62L, 64L) and is lithographically patterned to form a pair of openings, each having an area of a deep trench 45 to be subsequently formed. The pattern in the photoresist layer can be transferred into the at least one pad layer (62L, 64L). Subsequently, the pattern in the at least one pad layer (62L, 64L) can be transferred through the top semiconductor layer 30L, the buried insulator layer 20, and an upper portion of the bottom semiconductor layer 10 by an anisotropic etch that employs the at least one pad layer (62L, 64L) as an etch mask. A pair of deep trench 45 can be formed for each opening in the at least one pad layer (62L, 64L). The photoresist can be removed by aching, or can be consumed during the etch process that forms the deep trench 45.

The sidewalls of each deep trench 45 can be substantially vertically coincident among the various layers (64L, 62L, 30L, 20, 10) through which the deep trench 45 extends. As used herein, sidewalls of multiple elements are “vertically coincident” if the sidewalls of the multiple elements overlap in a top-down view such as FIG. 1A. As used herein, sidewalls of multiple elements are “substantially vertically coincident” if the lateral offset of the sidewalls of the multiple elements from a perfectly vertical surface is within 5 nm. The depth of each deep trench 45 as measured from the plane of the topmost surface of the SOI substrate (10, 20, 30L) to the bottom surface of the deep trench 45 can be from 500 nm to 10 microns, although lesser and greater depths can also be employed. The lateral dimensions of each deep trench 45 can be limited by the lithographic capabilities, i.e., the ability of a lithographic tool to print the image of an opening on the photoresist layer. In one embodiment, the “width,” i.e., a sidewall to sidewall distance, of each deep trench 45 along the direction parallel to the B-B′ plane and along the direction perpendicular to the B-B′ plane can be from 32 nm to 150 nm, although lesser dimensions can be employed with availability of lithographic tools capable of printing smaller dimensions in the future.

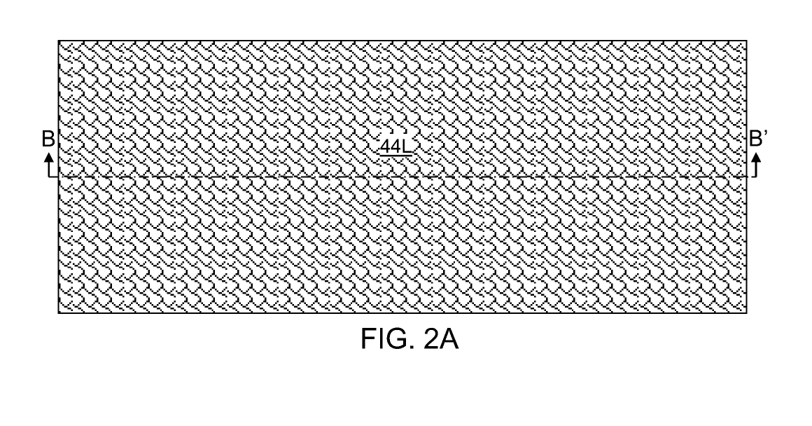

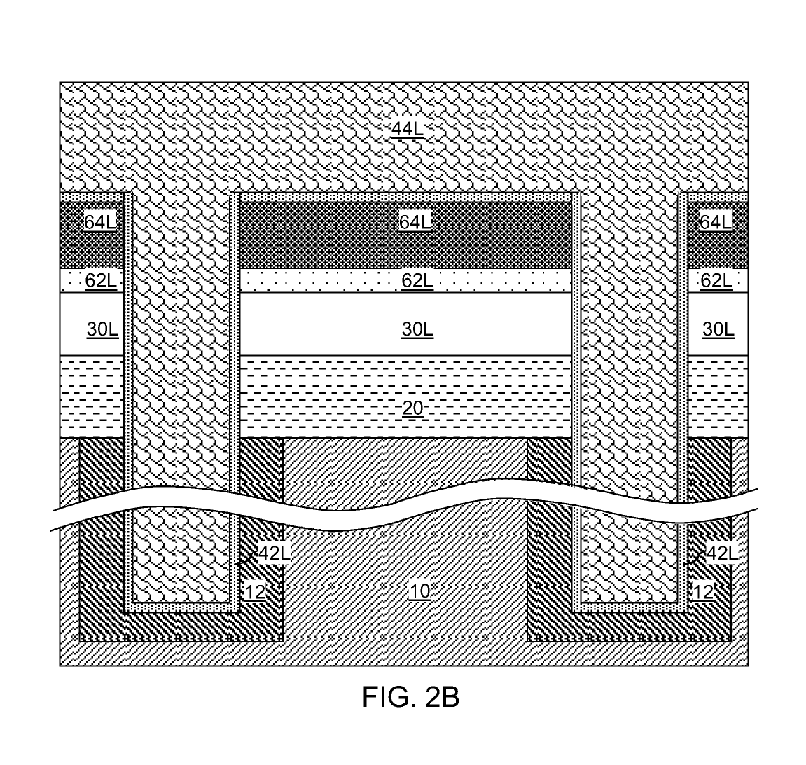

Referring to FIGS. 2A and 2B, buried plates 12 can be formed by doping a portion of the bottom semiconductor layer 12 in proximity of sidewalls of the bottom semiconductor layer 10 within each deep trench 45. Dopants can be introduced, for example, by outdiffusion from a dopant-including disposable material (such as a doped silicate glass) or by ion implantation as known in the art. Further, any other method of forming buried plates 12 in the bottom semiconductor layer 10 of an SOI substrate (10, 20, 30L) can be employed in lieu of outdiffusion from a dopant-including disposable material or ion implantation.

In one embodiment, the buried plates 12 can be doped with dopants of a second conductivity type which is the opposite of the first conductivity type. For example, the first conductivity type can be p-type and the second conductivity type can be n-type, or vice versa. A p-n junction is formed between the remaining portion of the bottom semiconductor layer 10 and each buried plate 12. The dopant concentration in the buried plates 12 can be, for example, from 1.0×10¹⁸/cm³ to 2.0×10²¹/cm³, and typically from 5.0×10¹⁸/cm³ to 5.0×10¹⁹/cm³, although lesser and greater dopant concentrations can also be employed.

A node dielectric layer 42L can be deposited conformally on all physically exposed sidewalls in the deep trench 42L and on the top surface of the upper pad layer 64L. The node dielectric layer 42L can include any dielectric material that can be employed as a node dielectric material in a capacitor known in the art. For example, the node dielectric layer 42L can include at least one of silicon nitride and a dielectric metal oxide material such as high dielectric constant (high-k) gate dielectric material as known in the art.

An inner electrode layer 44L can be deposited to completely fill the deep trenches 45. The inner electrode layer 44L includes a conductive material, which can be a metallic material or a doped semiconductor material. The metallic material can be an elemental metal such as W, Ti, Ta, Cu, or Al, or an alloy of at least two elemental metals, or a conductive metallic nitride of at least one metal, or a conductive metallic oxide of at least one metal. The doped semiconductor material can be a doped elemental semiconductor material, a doped compound semiconductor material, or an alloy thereof. The inner electrode layer 44L can be deposited by physical vapor deposition (PVD), chemical vapor deposition (CVD), electroplating, electroless plating, or a combination thereof. The inner electrode layer 44L is deposited to a thickness that is sufficient to completely fill the deep trenches 45.

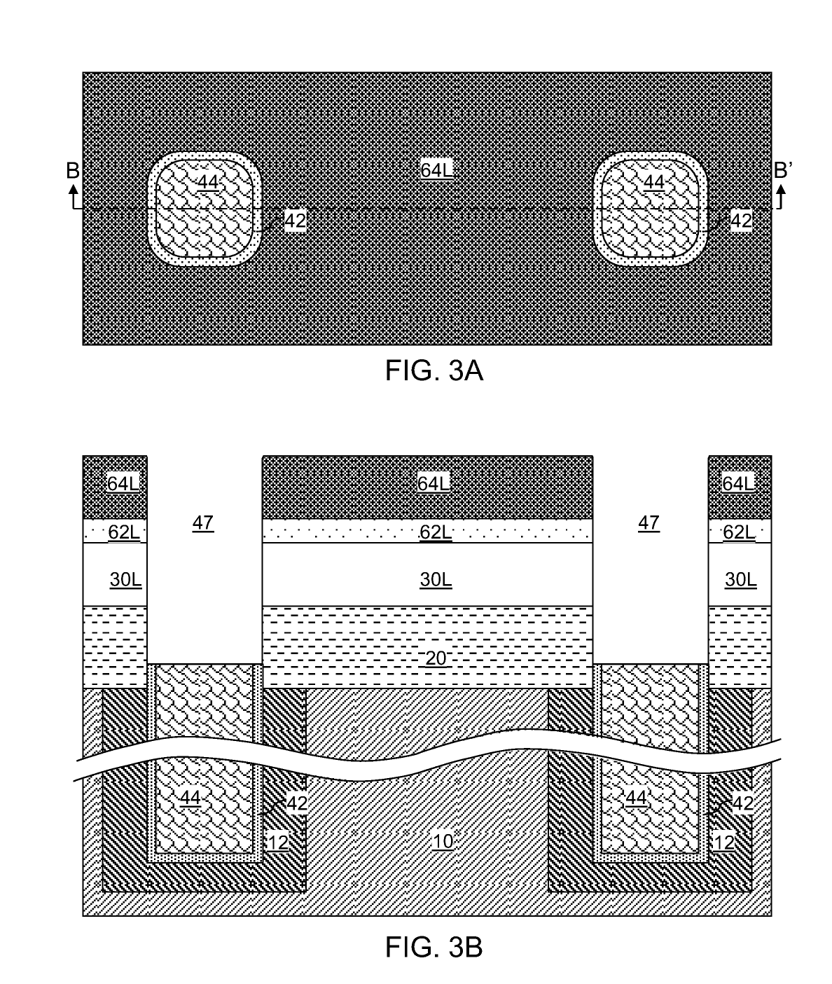

Referring to FIGS. 3A and 3B, the inner electrode layer 44L is vertically recessed to a level between the top surface of the buried insulator layer 20 and the bottom surface of the buried insulator layer 20 by a recess etch. The recess etch of the conductive material layer can employ an anisotropic etch such as a reactive ion etch, an isotropic etch such as a wet etch, or a combination thereof. The recess etch can be selective to the material of the node dielectric layer 42L.

An inner electrode 44 including the conductive material of the inner electrode layer 44L can be formed in each deep trench 45. The topmost surface of each inner electrode 44 is substantially planar, and is located between the level of the top surface of the buried insulator layer 20 and the level of the bottom surface of the buried insulator layer 20. A surface is substantially planar if the planarity of the surface is limited by microscopic variations in surface height that accompanies semiconductor processing steps known in the art. A cavity 47 is formed above each inner electrode 44.

The physically exposed portions of the node dielectric layer 42L can be patterned by an etch, which can be a wet etch. For example, if the node dielectric layer 42L includes silicon nitride, the physically exposed portions of the node dielectric layer 42L can be removed by a wet etch employing hot phosphoric acid. Each remaining portion of the node dielectric layer 42L within the deep trenches 45 constitutes a node dielectric 42. Each set of the buried plate 12, the node dielectric 42, and the inner electrode 44 around a deep trench 45 constitutes a trench capacitor (12, 42, 44). The buried plate 12 is an outer node of the trench capacitor, the node dielectric 42 is the dielectric separating the outer electrode from the inner electrode, and the inner electrode 44 is the inner electrode of each trench capacitor. The trench capacitors are embedded within the SOI substrate (10, 12, 20, 30L). The buried insulator layer 20 overlies the buried plates 12 (i.e., the outer electrode).

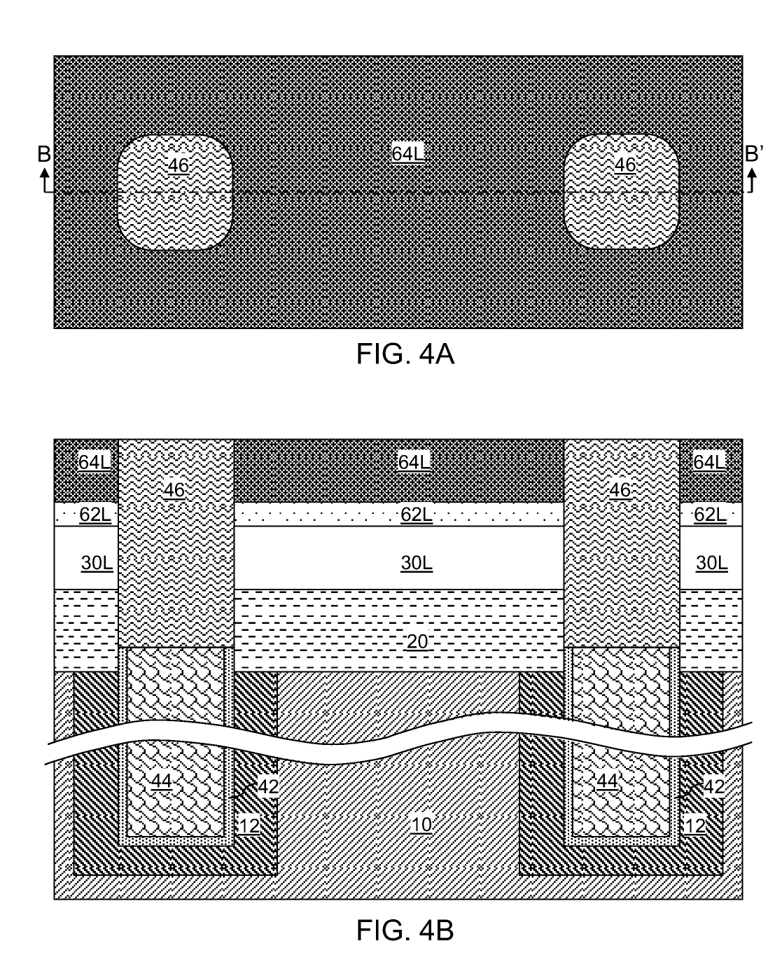

Referring to FIGS. 4A and 4B, conductive strap structures 46 can be formed, for example, by depositing a conductive material within the cavities 47 and above the at least one pad layer (62L, 64L), and subsequently planarizing the conductive material. Specifically, the conductive material can be a metallic material or a doped semiconductor material. The metallic material can be an elemental metal such as W, Ti, Ta, Cu, or Al, or an alloy of at least two elemental metals, or a conductive metallic nitride of at least one metal, or a conductive metallic oxide of at least one metal. The doped semiconductor material can be a doped elemental semiconductor material, a doped compound semiconductor material, or an alloy thereof. The conductive material can be deposited by physical vapor deposition (PVD), chemical vapor deposition (CVD), electroplating, electroless plating, or a combination thereof. The conductive material may be deposited to a thickness that is sufficient to completely fill the cavities 47 as illustrated in FIGS. 3A and 3B. The conductive material can be planarized, for example, by chemical mechanical planarization (CMP) employing the upper pad layer 54L as a stopping layer. The top surface of the conductive strap structure 46 can be substantially coplanar with the top surface of the upper pad layer 64L.

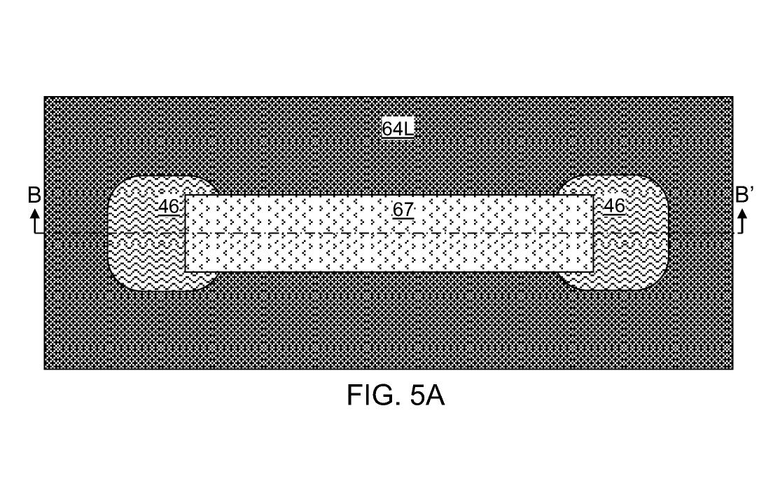

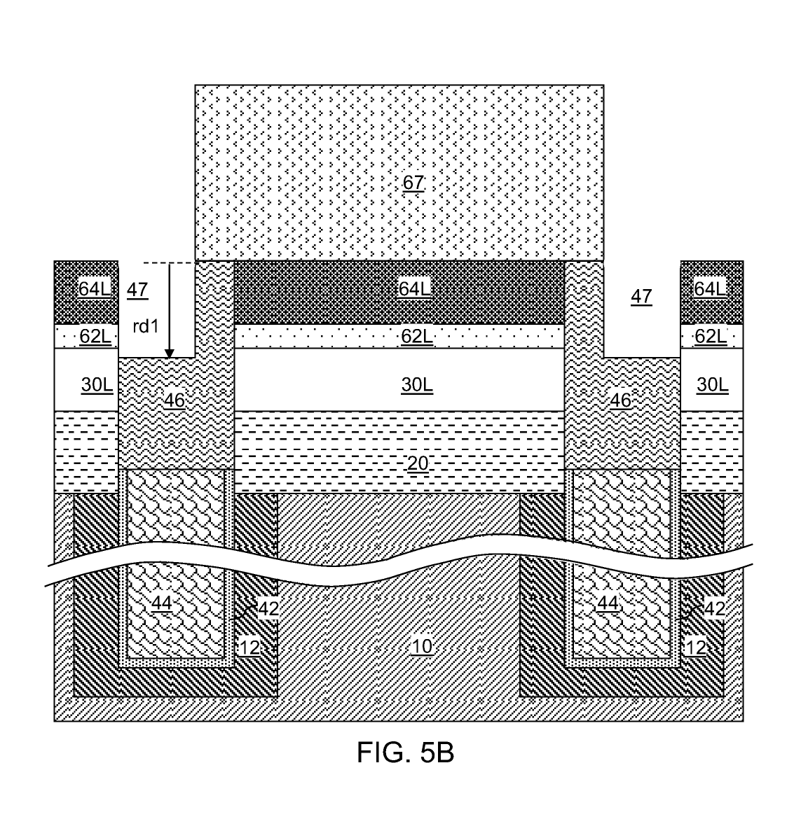

Referring to FIGS. 5A and 5B, a photoresist layer 67 can be applied over the upper pad layer 64L and the conductive strap structures 46. Subsequently, the photoresist layer 67 can be patterned so that a remaining portion of the photoresist layer 67 overlies portions of each interface between the at least one pad layer (62L, 64L) and the conductive strap structures 46. In one embodiment, the patterned photoresist layer 67 can have a horizontal cross-sectional area of a rectangle such that the short edges of the rectangle overlie the conductive strap structures 46.

Portions of the conductive strap structure 46 that do not underlie the photoresist layer 67 may be vertically recessed by a first anisotropic etch to a first recess depth rd1. The first anisotropic etch can be selective to the upper pad layer 64L. In one embodiment, the first recess depth can be greater than the thickness of the top semiconductor layer 30L, and less than the thickness of the buried insulator layer 20. A cavity 47 can be formed within each recessed region.

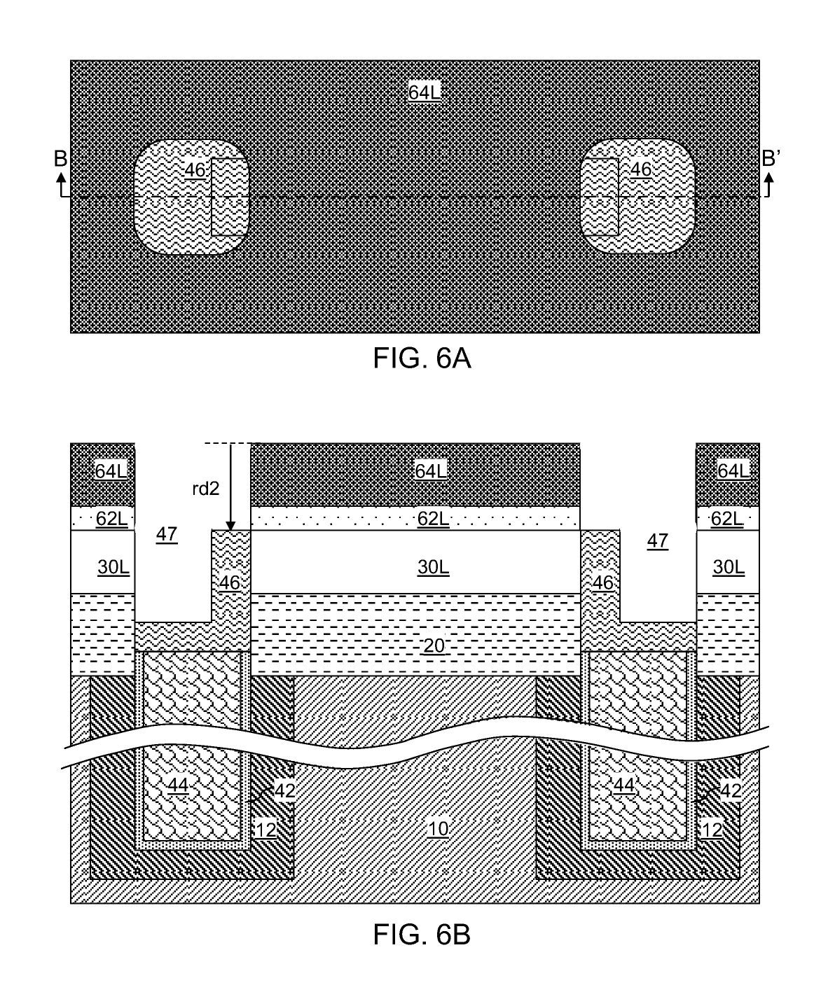

Referring to FIGS. 6A and 6B, the photoresist layer 67 can be removed, for example, by ashing. The top surfaces of the conductive strap structures 46 can be vertically recessed by a second anisotropic etch to a second recess depth rd2. The second anisotropic etch can be selective to the upper pad layer 64L. The second recess depth is less than the sum of the thicknesses of the upper pad layer 64L, the lower pad layer 62L, and the top semiconductor layer 30L. Thus, the topmost surfaces of the conductive strap structures 46 are located above the bottom surface of the top semiconductor layer 30L after the second anisotropic etch. A top surface of each conductive strap structure 46 is located at the depth corresponding to the sum of the first recess depth rd1 and the second recess depth rd2 from the top surface of the upper pad layer 64L. The sum of the first recess depth rd1 and the second recess depth is greater than the sum of the thicknesses of the upper pad layer 64L, the lower pad layer 62L, and the top semiconductor layer 30L, and is less than the sum of the thicknesses of the upper pad layer 64L, the lower pad layer 62L, the top semiconductor layer 30L, and the buried insulator layer 20.

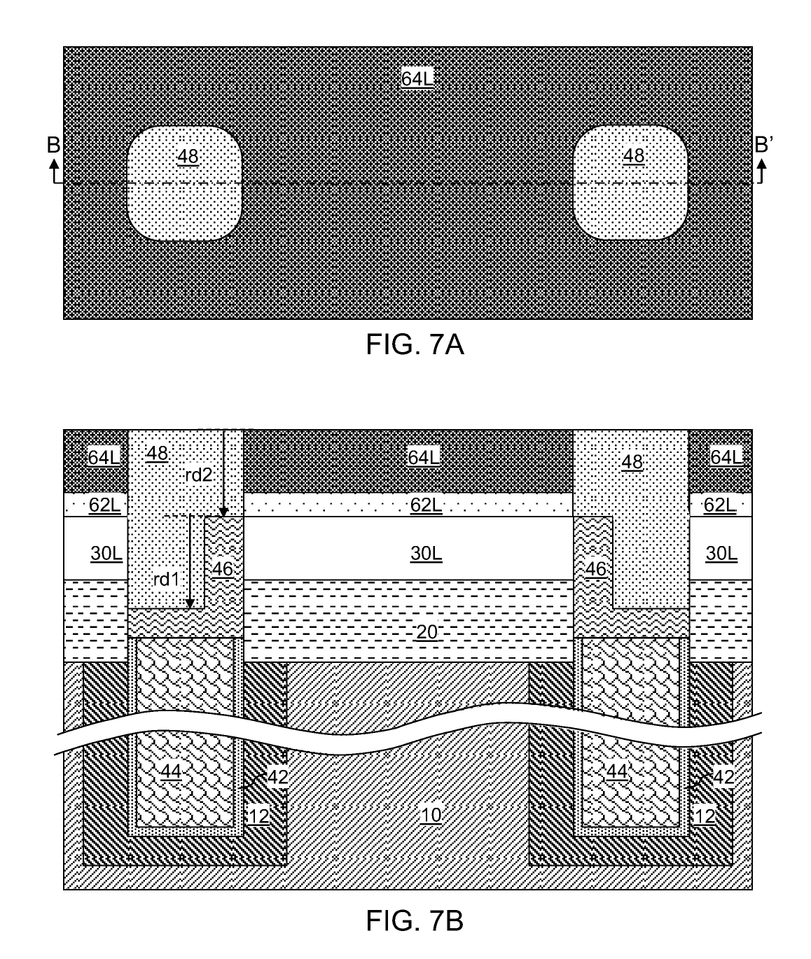

Referring to FIGS. 7A and 7B, a dielectric material can be deposited within the cavities 47 and above the at least one pad layer (62L, 64L), and can be subsequently planarized employing the upper pad layer 64L as a stopping layer to form dielectric capacitor caps 48. The dielectric material of the dielectric capacitor caps 48 is different from the dielectric material of the upper pad layer 64L. For example, the dielectric material of the upper pad layer 64L can be silicon nitride, and dielectric material of the dielectric capacitor caps 48 can be silicon oxide. The dielectric material of the dielectric capacitor caps 48 can be deposited, for example, by chemical vapor deposition (CVD).

Each dielectric capacitor cap 48 can be formed within an opening in the stack of the lower pad layer 62L and the upper pad layer 64L. Each dielectric capacitor cap 48 contacts the top surface of the conductive strap structure 46. Specifically, each dielectric capacitor cap 48 contacts a first planar top surface of the conductive strap structure 46 located at the second recess depth rd2 from the topmost surface of the dielectric capacitor cap 48, a second planar top surface of the conductive strap structure 46 that is vertically offset from the first planar top surface by the first recess depth rd1, and a sidewall surface of the conductive strap structure 46 extending from the first planar top surface to the second planar top surface. Further, the entirety of sidewalls of the dielectric capacitor cap 48 is vertically coincident with the entirety of sidewalls of the conductive strap structure 46.

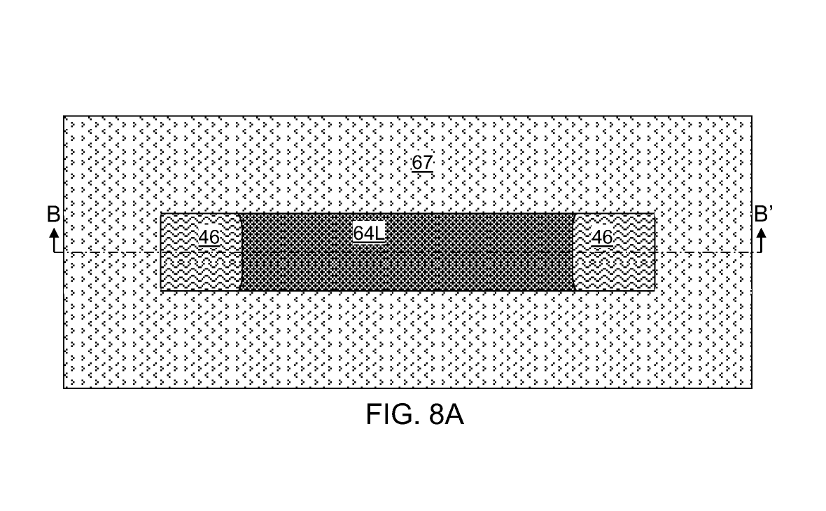

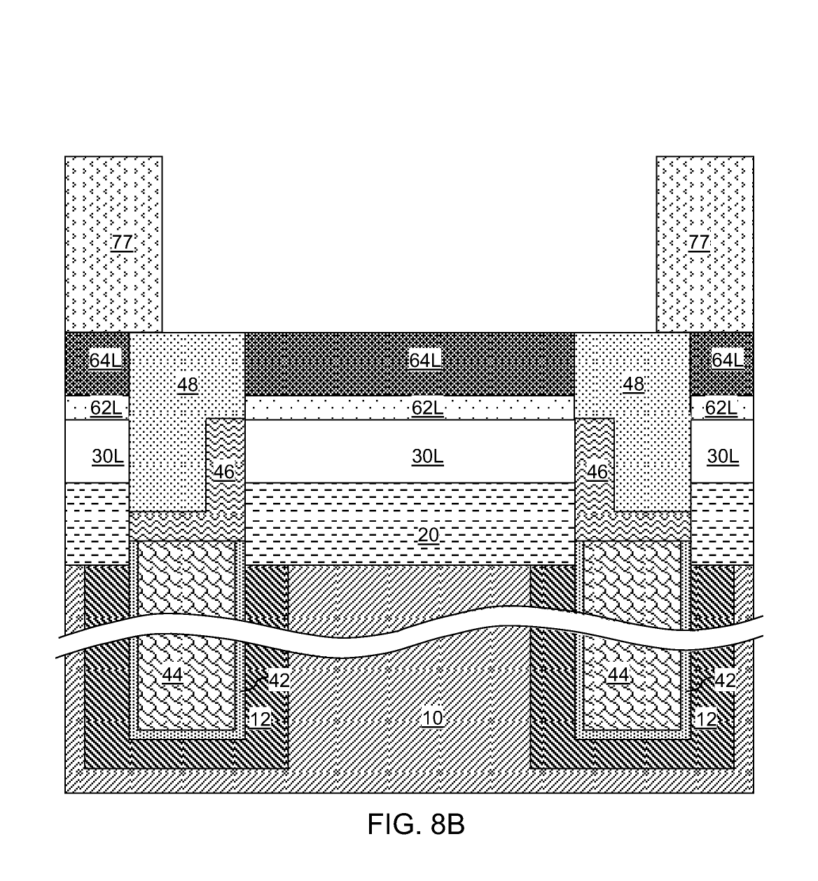

Referring to FIGS. 8A and 8B, a photoresist layer 77 can be formed over the upper pad layer 64 and the dielectric capacitor caps 48, and can be lithographically patterned to form an opening overlying a portion of the top semiconductor layer 30L and portion of each of the two dielectric capacitor caps 48. The portion of the top semiconductor layer 30L laterally extends from one of the two conductive strap structures 46 to the other of the two conductive strap structures 46. In one embodiment, the horizontal cross-sectional shape of the opening in the photoresist layer 77 can be a rectangle having a pair of short sides that overlie the dielectric capacitor caps 48.

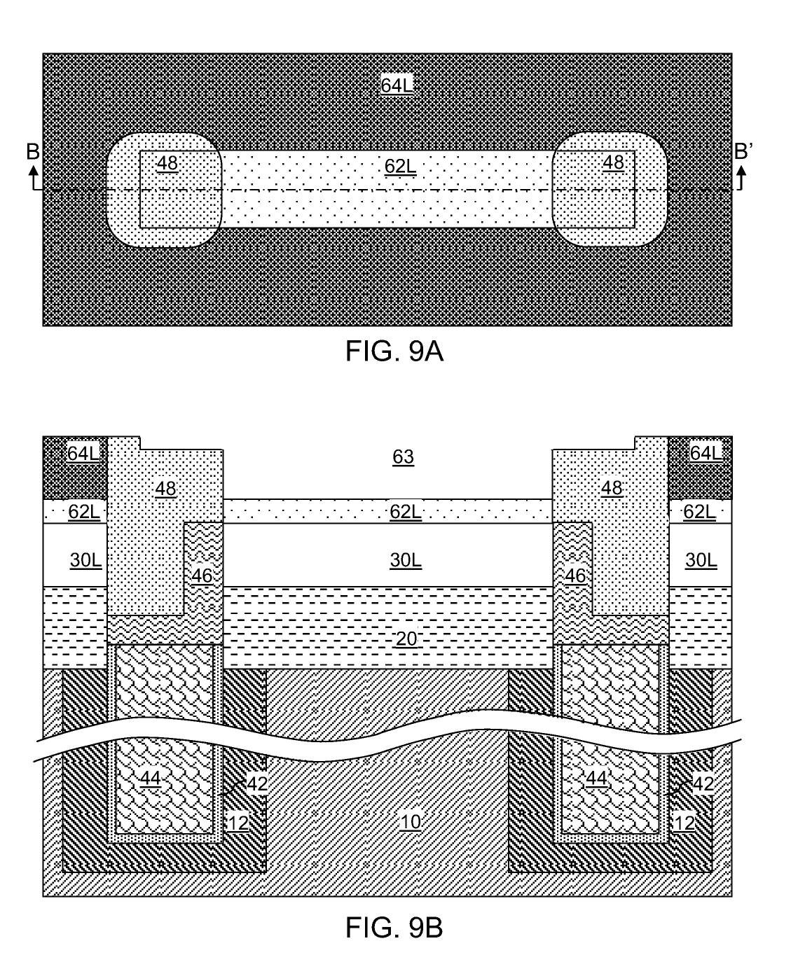

Referring to FIGS. 9A and 9B, an anisotropic etch can be employed to remove the material of the upper pad layer 64L with at least some selectivity to the material of the dielectric capacitor caps 48. If the upper pad layer 64L includes silicon nitride, and the dielectric capacitor caps 48 include silicon oxide, an anisotropic etch that removes silicon nitride with selectivity to silicon oxide can be employed. The portion of the upper pad layer 64L underlying the opening in the photoresist layer 77 can be removed.

A composite pattern of the intersection of the opening in the photoresist layer 77 and the area of the upper pad layer 64L (i.e., the area of the SOI substrate less the areas of the dielectric capacitor caps 48) can be transferred into the upper pad layer 64L to form a trough 63. The trough is laterally surrounded by sidewalls of the upper pad layer 64L and sidewalls of the dielectric capacitor caps 48. Thus, the trough 63 overlies a portion of the top semiconductor layer 30L, a sidewall of each dielectric capacitor cap 48 is physically exposed within the trough 63. The portion of the top surface of each dielectric capacitor cap 48 located within the opening in the photoresist layer 77 can be recessed relative to the remainder of the top surface of each dielectric capacitor caps 48 that is covered with the photoresist layer 77 during the anisotropic etch. The photoresist layer 77 is subsequently removed, for example, by ashing.

In one embodiment, the sidewalls of the upper pad layer 64L physically exposed to the trough 63 can be parallel to each other and extend from one of the two dielectric capacitor caps 48 to the other of the two dielectric capacitor caps 48. The sidewalls of the dielectric capacitor caps 48 physically exposed to the trough 63 can be convex (if the periphery of the dielectric capacitor caps 48 is circular or elliptical) or include convex portions (if the periphery of the dielectric capacitor caps includes curved portions).

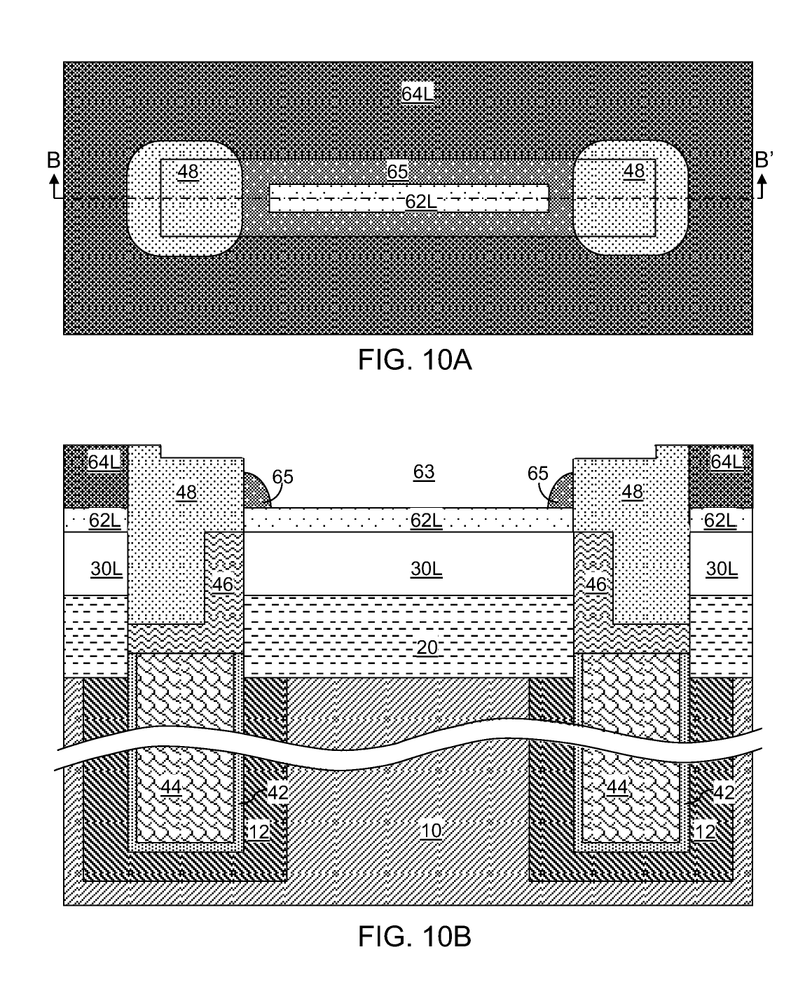

Referring to FIGS. 10A and 10B, a fin-defining spacer 65 can be formed within the trough 63 on sidewalls of the upper pad layer 64L and the sidewalls of the dielectric capacitor caps 48. The fin defining spacer 65 can be formed by deposition of a substantially conformal material layer and an anisotropic etch that removes horizontal portions of the substantially conformal material layer. The substantially conformal material layer includes a material that is different from the materials of the lower pad layer 62L, the upper pad layer 64L, and the dielectric capacitor caps 48. The material of the substantially conformal material layer can be a dielectric material, a semiconductor material, or a metallic material. For example, the material of the substantially conformal material layer can be amorphous carbon, a dielectric metal oxide, polysilicon, or a metallic material such as Ti, Ta, W, TiN, TaN, or WN. In one embodiment, the material of the substantially conformal material layer can be amorphous carbon.

The substantially conformal material layer can be deposited, for example, by chemical vapor deposition (CVD). The thickness of the substantially conformal material layer, which is substantially the same as the thickness of the fin-defining spacer 65 as measured at the base, is less than half the width of the trough 37. In one embodiment, the thickness of the fin-defining spacer 65 can be from 5 nm to 100 nm, although lesser and greater thicknesses can also be employed. In one embodiment, the thickness of the substantially conformal material layer can be from 10 nm to 50 nm.

The fin-defining spacer 65 can be formed on the sidewalls of a set of masking structures that include the upper pad layer 64L and the dielectric capacitor caps 48. The fin-defining spacer 65 can be formed as a structure that is topologically homeomorphic to a torus, i.e., a structure that can be contiguously deformed into a torus without creating or destroying a singularity (such as a hole within a plane).

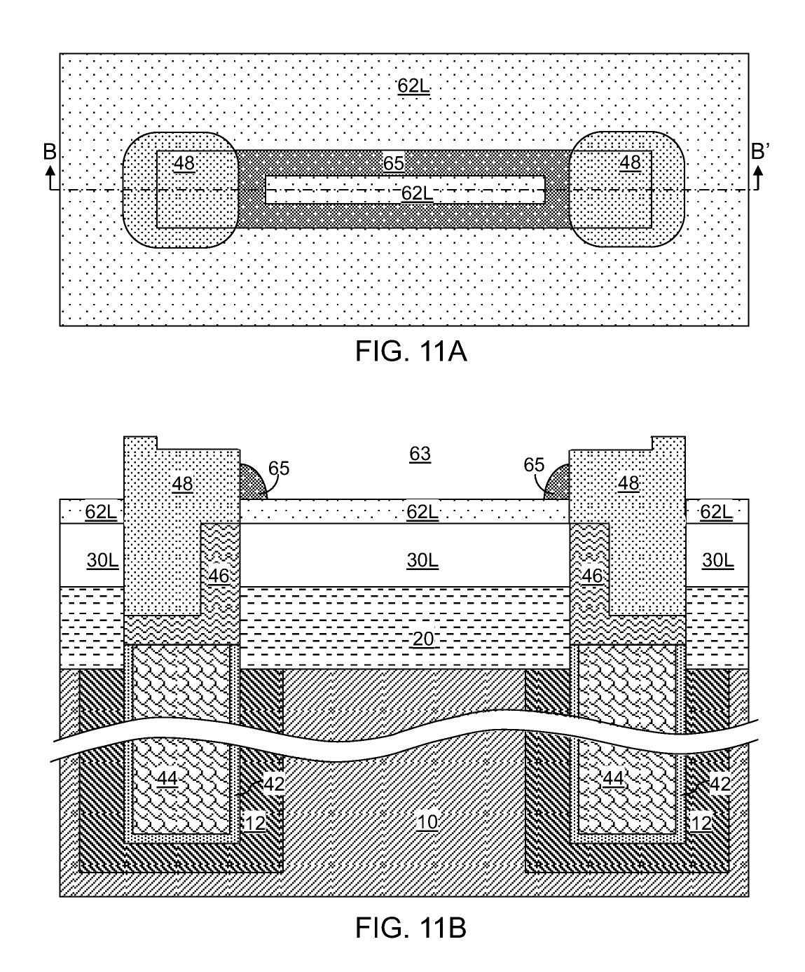

Referring to FIGS. 11A and 11B, the upper pad layer 64L can be removed selective to the materials of the lower pad layer 63L, the fin-defining spacer 65, and the dielectric capacitor caps 48. The upper pad layer 64L can be removed, for example, by a wet etch. In one embodiment, if the lower dielectric layer 62L includes a dielectric metal oxide, the fin-defining spacer 65 includes amorphous carbon, the dielectric capacitor caps 48 include silicon oxide, and the upper pad layer 64L includes silicon nitride, the upper pad layer 64L can be removed selective to the materials of the lower pad layer 63L, the fin-defining spacer 65, and the dielectric capacitor caps 48 by a wet etch employing hot phosphoric acid.

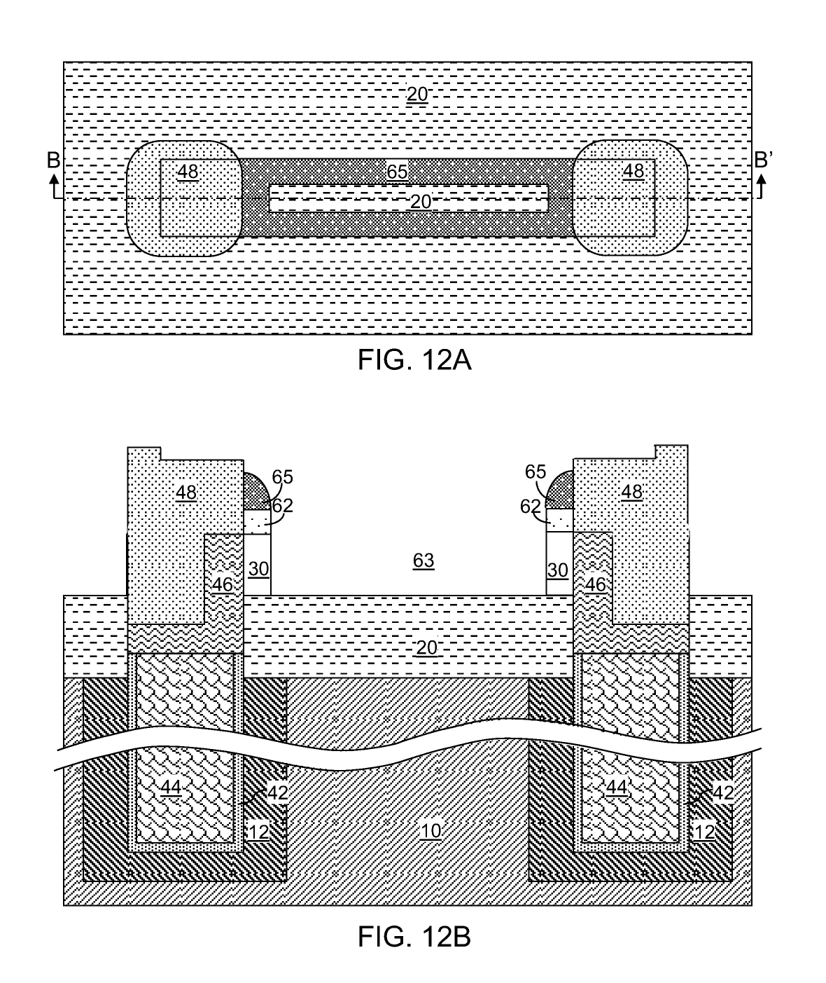

Referring to FIGS. 12A-12E, the lower pad layer 62L and the top semiconductor layer 30L can be etched employing the fin-defining spacer 65 as an etch mask. Specifically, the pattern in the fin-defining spacer 65 may be transferred into the lower pad layer 62L by an anisotropic etch that employs the fin-defining spacer 65 as an etch mask. The remaining portion of the lower pad layer 62L constitutes a lower pad portion 62 having a same horizontal cross-sectional area as the area of the base of the fin-defining spacer 65.

Subsequently, the pattern of the fin-defining spacer 65 can be transferred into the top semiconductor layer 30L. The top semiconductor layer 30L may be etched employing, as an etch mask, at least one of the fin-defining spacer 65 and the lower pad portion 62, i.e., the remaining portion of the lower pad layer after the etching of the lower pad layer 62L. The remaining portion of the top semiconductor layer 30L constitutes a semiconductor fin 30 having a uniform width throughout. Thus, the semiconductor fin 30 is formed by transferring the pattern of the fin-defining spacer 65 into the top semiconductor layer 30L. The width of the semiconductor fin 30 can be substantially the same as the width of the base of the fin-defining spacer 65. Further, the horizontal area of the semiconductor fin 30 is the same as the area of the base of the fin-defining spacer 65.

In one embodiment, the fin-defining spacer 65 is employed as the etch mask during the etching of the top semiconductor layer 30L. Upon formation of the semiconductor fin 30, the fin-defining spacer 65 and the lower pad portion 62 can be removed selective to the semiconductor fin 30, for example, by a wet etch, a dry etch, or a combination thereof.

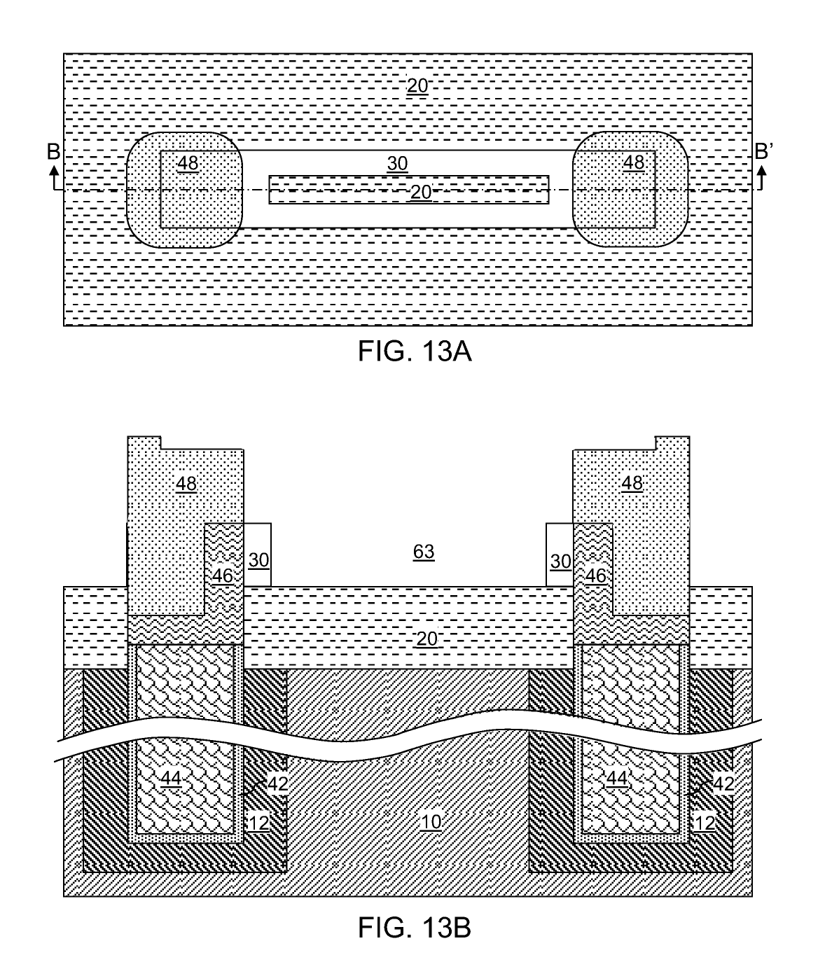

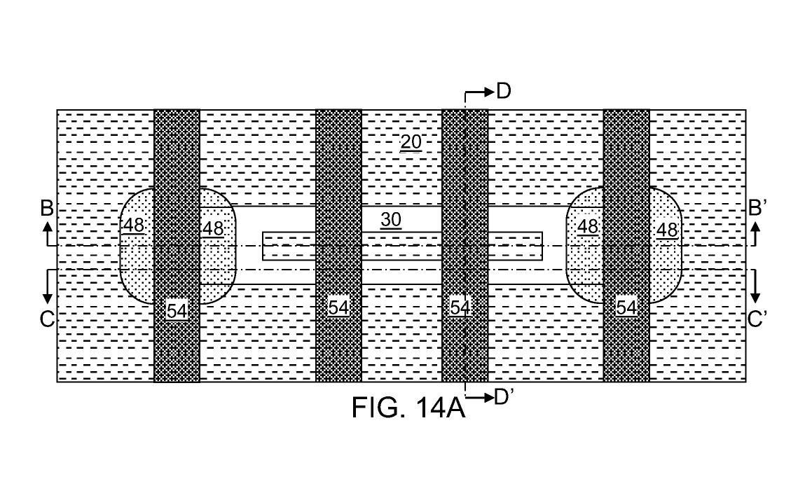

Referring to FIGS. 13A and 13B, the semiconductor fin 30 contacts the conductive strap structures 48 upon formation of the semiconductor fin 30. The semiconductor fin 30 is topologically homeomorphic to a torus, and laterally contacts the conductive strap structure 46. In one embodiment, the semiconductor fin 10 can include two pairs of parallel edges (e.g., the edges that are parallel to plane B-B′). A trough 63 laterally surrounded by the semiconductor fin 30 is formed over the buried insulator layer 20. The portions of the semiconductor fin 30 between each pair of parallel edges along the direction connecting the two dielectric capacitor caps 48 (i.e., the two pairs of edges along plane B-B′) to as linear portions. Each linear portion of the semiconductor fin 30 has a uniform width throughout.

A sidewall of the conductive strap structure 48 that contacts the semiconductor fin 30 is herein referred to as a proximal sidewall of the conductive strap structure 48. A sidewall of the conductive strap structure 48 that is located on the opposite side of the proximal sidewall of the conductive strap structure 48 is herein referred to as a distal sidewall. The buried insulator layer 20 is in contact with the bottom surface of the semiconductor fin 30.

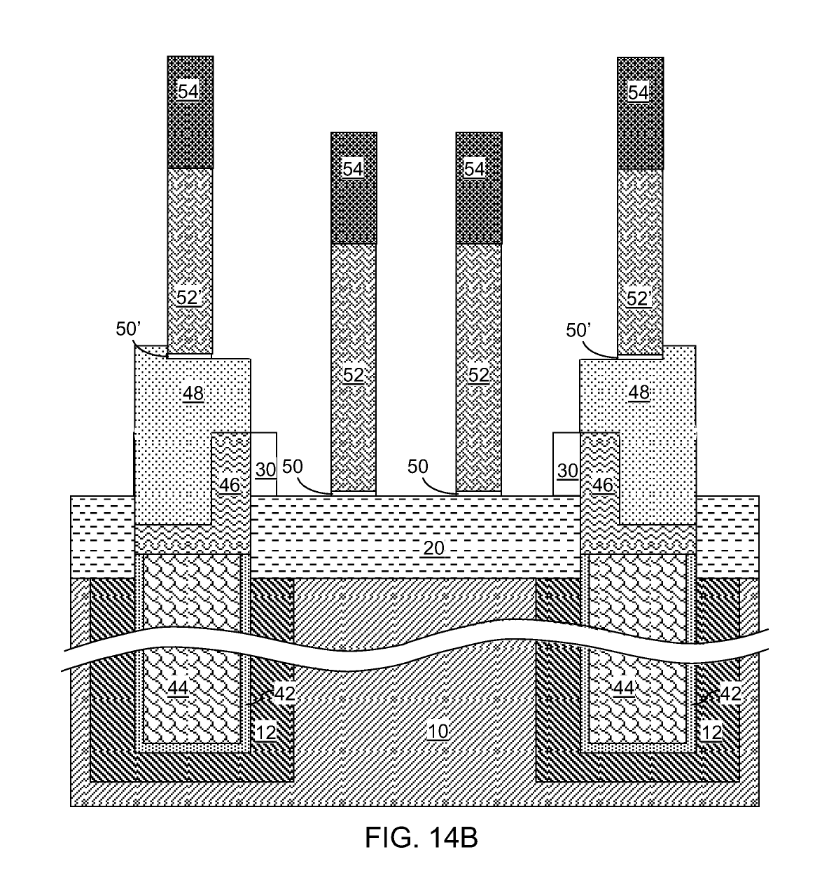

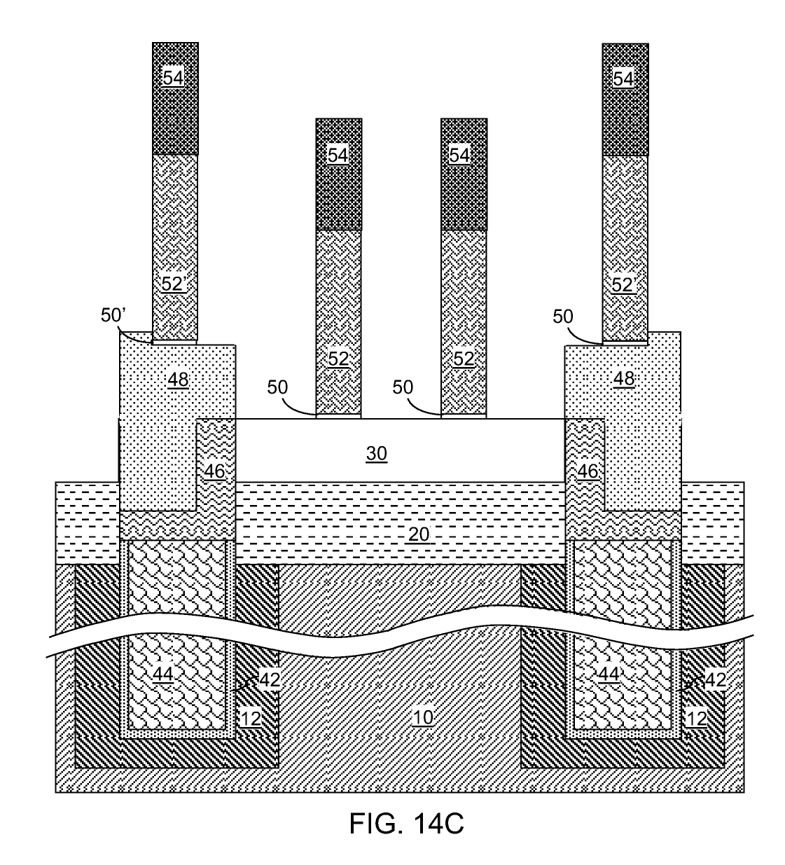

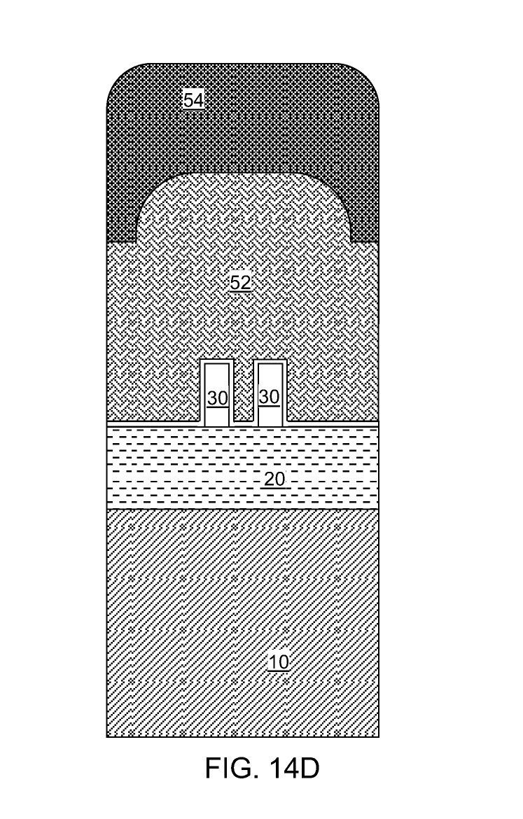

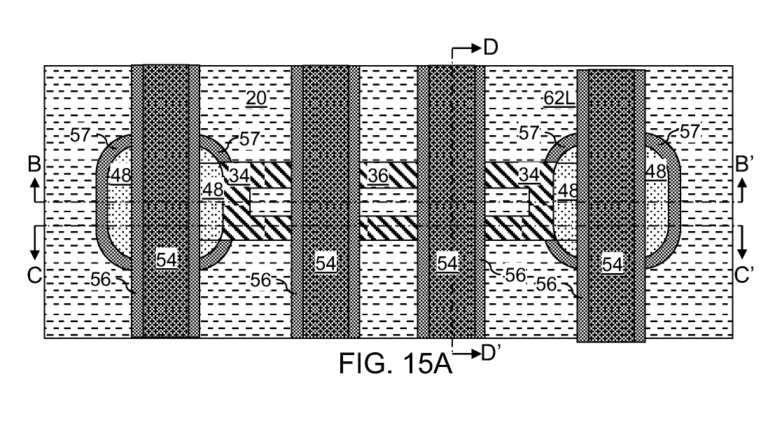

Referring to FIGS. 14A-14D, a stack of gate level layers can be deposited and lithographically patterned to form various gate stacks. For example, the gate level layers can include a gate dielectric layer, a gate electrode layer, and a gate cap layer. The gate dielectric layer can include any gate dielectric material known in the art, and can be formed by conversion of surface portions of a semiconductor material (e.g., the semiconductor material of the semiconductor fin 30, deposition of a dielectric material, or a combination thereof. The gate dielectric layer can include a dielectric semiconductor-containing compound (e.g., silicon oxide, silicon nitride, and/or silicon oxynitride) and/or a dielectric metal compound (e.g., dielectric metal oxide, dielectric metal nitride, and/or dielectric metal oxynitride). The gate electrode layer includes at least one conductive material, and can include a doped semiconductor material and/or a metallic material. The gate electrode layer can optionally include a work function metal layer that tunes the threshold voltage of the access transistor to be formed. The gate cap layer includes a dielectric material such as silicon oxide, silicon nitride, and/or silicon oxynitride.

The gate level layers may be patterned by a combination of lithography and etch to form gate stacks, which include active gate stacks straddling over the two parallel portions of the semiconductor fin 30, and a passive gate stack straddling over the dielectric capacitor cap 48. Remaining portions of the gate dielectric layer constitute a gate dielectric 50 (which is also referred to as an active gate dielectric) within each active gate stack (50, 52, 54) and a passing gate dielectric 50′ within each passing gate stack (50′, 52′, 54). Remaining portions of the gate electrode layer constitute a gate electrode 52 (which is also referred to as an active gate electrode) within each active gate stack (50, 52, 54) and a passing gate electrode 52′ within each passing gate stack (50′, 52′, 54). Remaining portions of the gate cap layer constitute gate caps 54. It is understood that the active gate stack (50, 52, 54) and the passive gate stack (50′, 52′, 54) can be formed within an array environment in which each pair of a trench capacitor (12, 42, 44) and an access transistor is a cell of a dynamic random access memory (DRAM) array, and that each active gate stack (50, 52, 54) can extend to become a passing gate stack (50′, 52′, 54) for an adjacent DRAM cell.

Each gate dielectric 50 straddles over portions of the semiconductor fin 30 that correspond to a pair of channel regions of an access field effect transistor to be subsequently formed. Each gate electrode 52 contacts the gate dielectric 50. The passing gate dielectrics 50′ can include the same material as the gate dielectrics 50 and/or have the same thickness as the gate dielectrics 50. The passing gate dielectrics 50′ are formed on the sidewalls of the conductive strap structure 46. The passing gate electrode includes the same material as the gate electrode 52, and is located over the dielectric capacitor cap 48 and on the passing gate dielectric 50′. The passing gate dielectric 50′ laterally contacts sidewalls of a dielectric capacitor cap 46 and sidewalls of a passing gate electrode 52′.

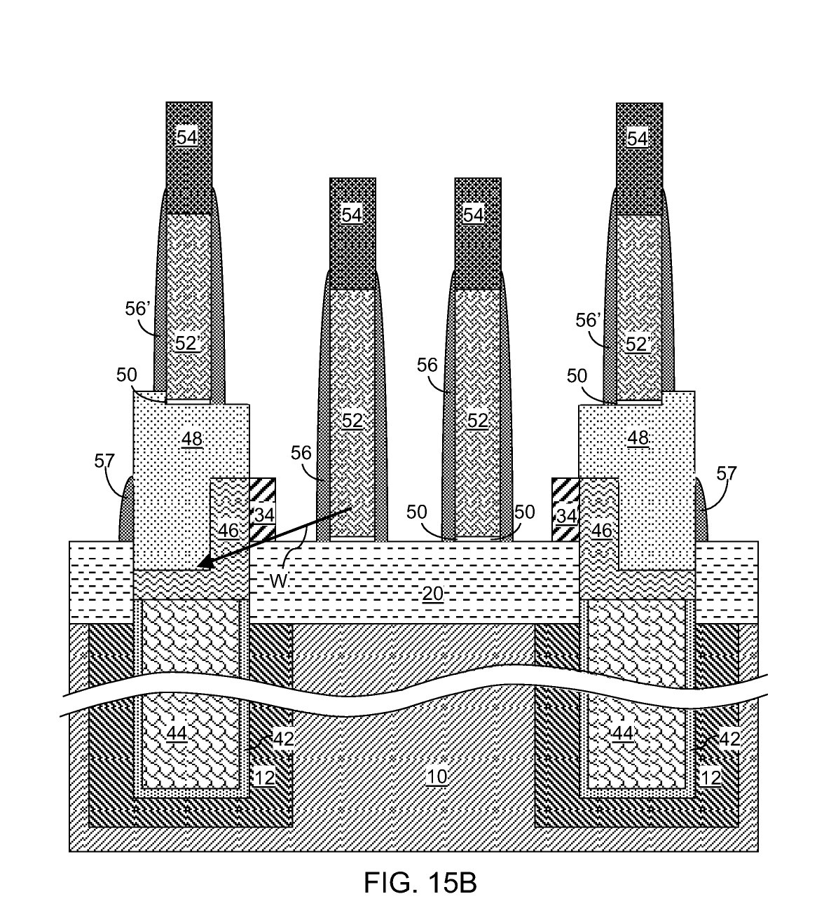

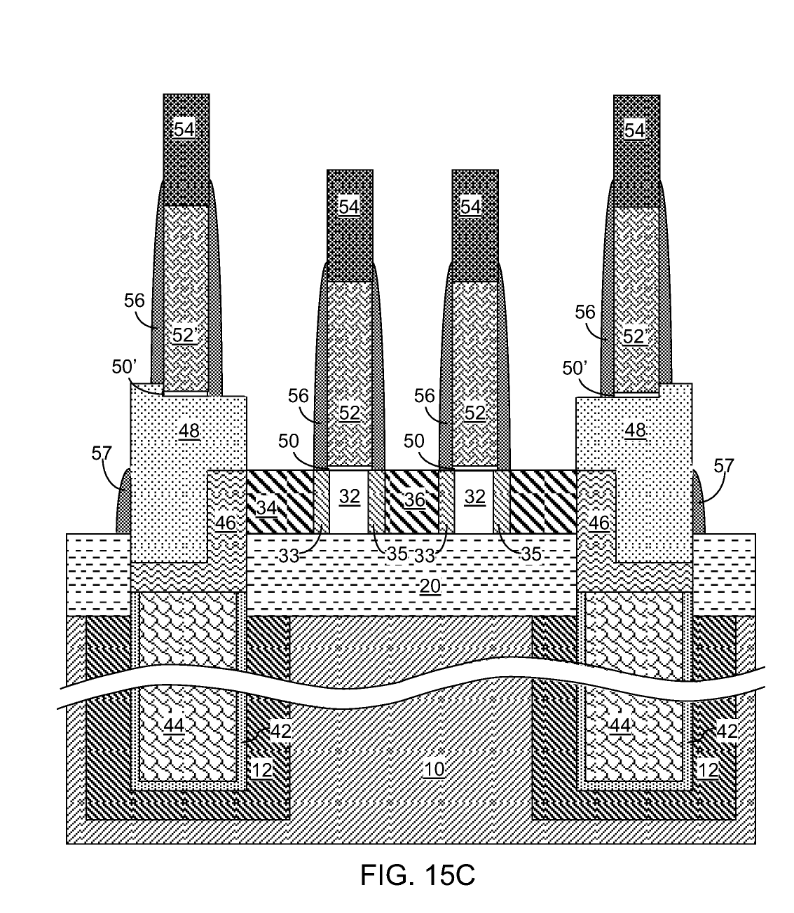

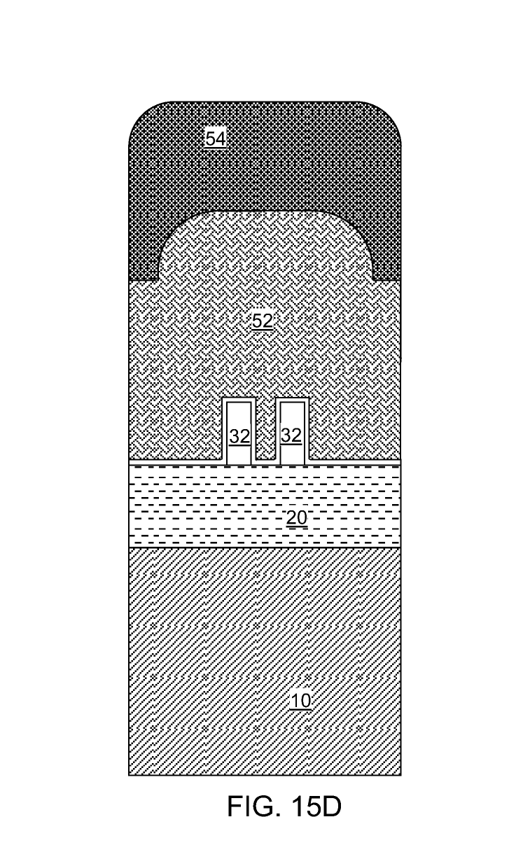

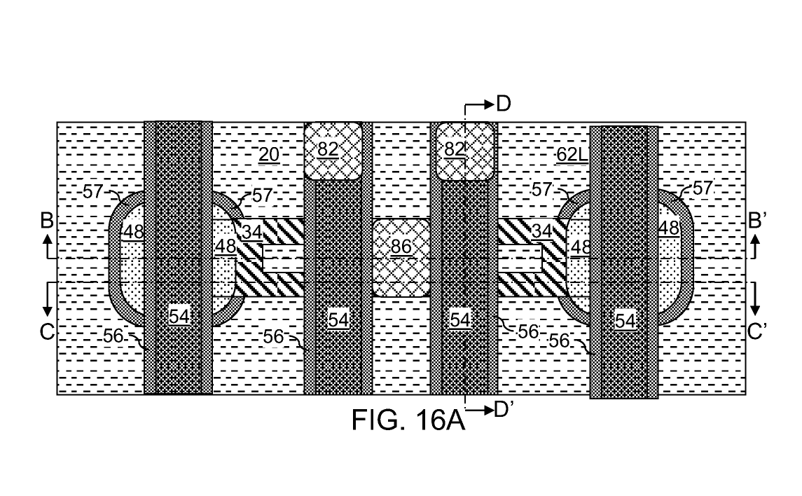

Referring to FIGS. 15A-15D, source extension regions 33 and drain extension regions 35 can be optionally formed by implanting p-type dopants or n-type dopants. If the access transistors to be formed are n-type field effect transistors, n-type dopants are implanted. If the access transistors to be formed are p-type filed effect transistors, p-type dopants are implanted. The active gate stack (50, 52, 54) and the passing gate stack (50′, 52′, 54) function as a masking layer during the ion implantation that forms the source extension regions 33 and the drain extension regions 35.

Gate spacers 56 can be formed by depositing a conformal dielectric layer and anisotropically etching the conformal dielectric layer. In one embodiment, the gate spacers 56 can include a dielectric material different from the dielectric material of the buried insulator layer 20. For example, if the buried insulator layer 20 includes silicon oxide, the gate spacers 56 can include silicon nitride. The etch process that removes horizontal portions of the conformal dielectric layer can be prolonged after horizontal portions of the conformal dielectric layer are removed so that vertical portions of the conformal dielectric layer on sidewalls of the semiconductor fin are removed. The topmost portions of the gate spacers 56 are vertically offset from the top surfaces of the gate caps 54. The thickness of the gate caps 54 can be selected such that the topmost portion of the gate spacers 56 contact a bottom portion of each gate cap 54, thereby encapsulating each gate electrode 52 and each passing gate electrode 52′.

Dopants of the same conductivity type as the dopants in the source extension regions 33 and the drain extension regions 35 can be implanted into the semiconductor fin employing the active gate stack (50, 52, 54), the passing gate stack (50′, 52′, 54), and the gate spacers 56 as an implantation mask. A source region 34 of each access transistor may be formed to continuously extend from one source extension region 33 located within one linear portion of the semiconductor fin to another source extension 33 in another linear portion of the semiconductor fin.

A pair of drain regions 36 can be formed on the opposite side of each source region 34 relative to the corresponding active gate stack (50, 52, 54). The pair of drain regions 36 is laterally spaced from each source region 34 by a pair of channel regions 32, which are portions of the semiconductor fin that are not implanted with dopants during the ion implantation steps that form the source extension regions 33, the drain extension regions 35, the source region 34, and the drain region 36. Sidewalls of the pair of channel regions 32 are parallel to sidewalls of the source regions 34 and the drain regions 36. The pair of drain regions 36 functions as a common drain node of the two access transistors. Each access transistor includes a pair of channel regions 32.

Each access transistor controls current flow into, and out of, the inner electrode 44 of a trench capacitor (12, 42, 44). The semiconductor fin includes the source regions 34 that laterally contact the conductive strap structures 46, two pairs of channel regions 32, the two drain regions 36, and optionally, the source extension regions 33 and the drain extension regions 35.

For each access transistor, the proximal sidewall of a conductive strap structure 46 has the least lateral offset from a pair of channel regions 32 underneath the active gate stack (50, 52, 54) of that access transistor among sidewalls of the conductive strap structure 46. The proximal sidewall of each conductive structure 46 is in contact with the semiconductor fin (34, 33, 32, 35, 36).

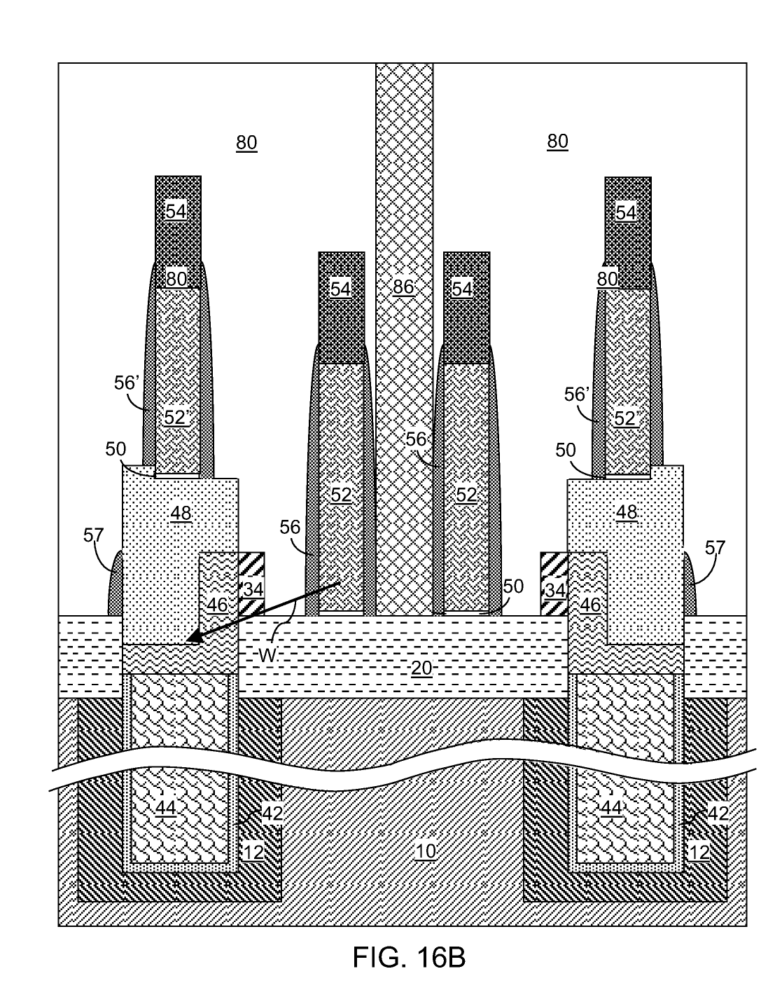

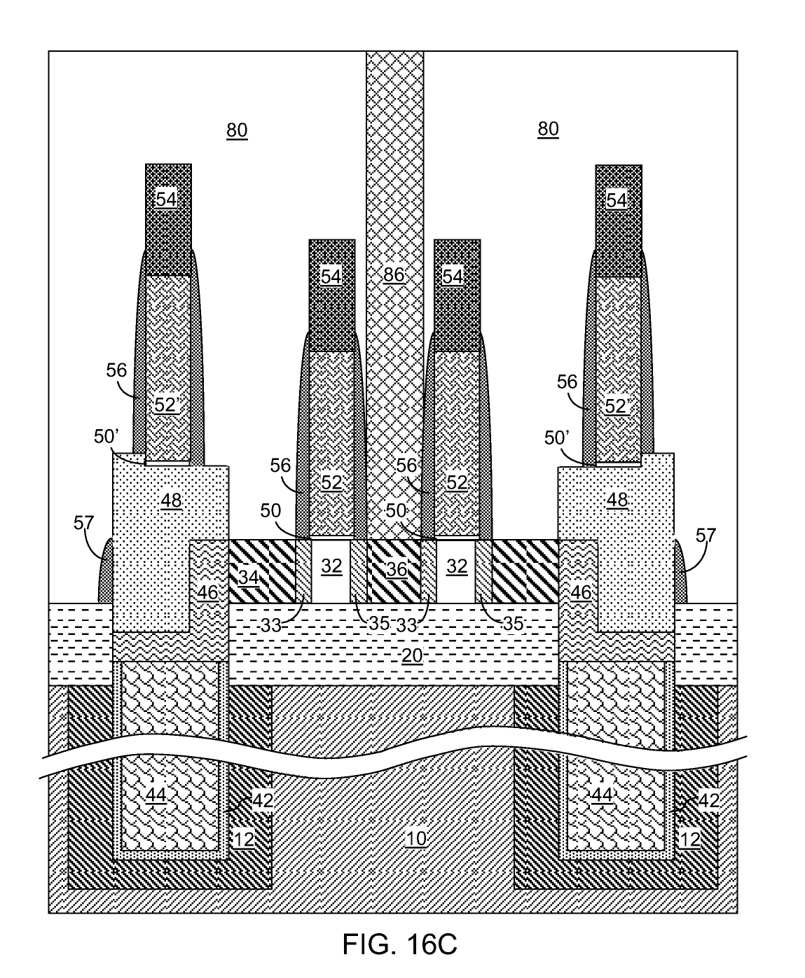

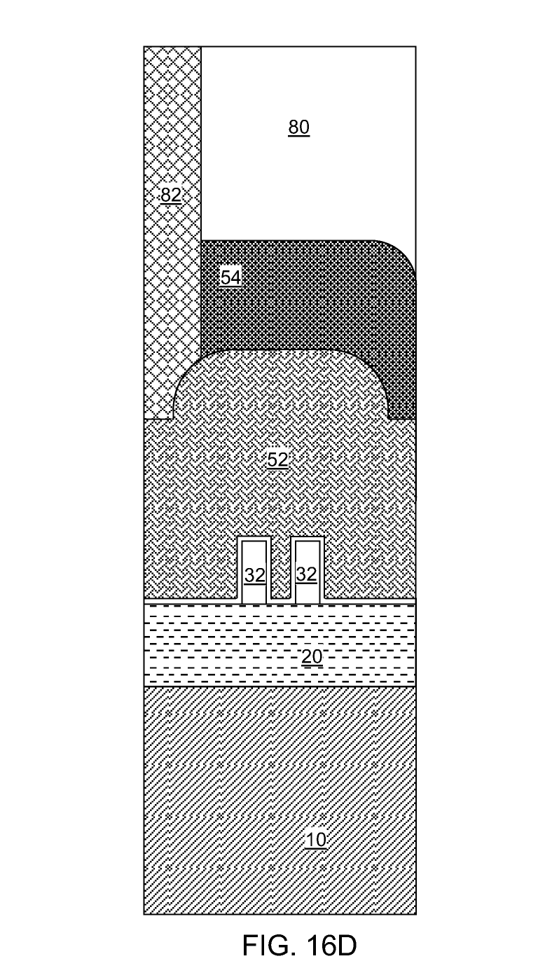

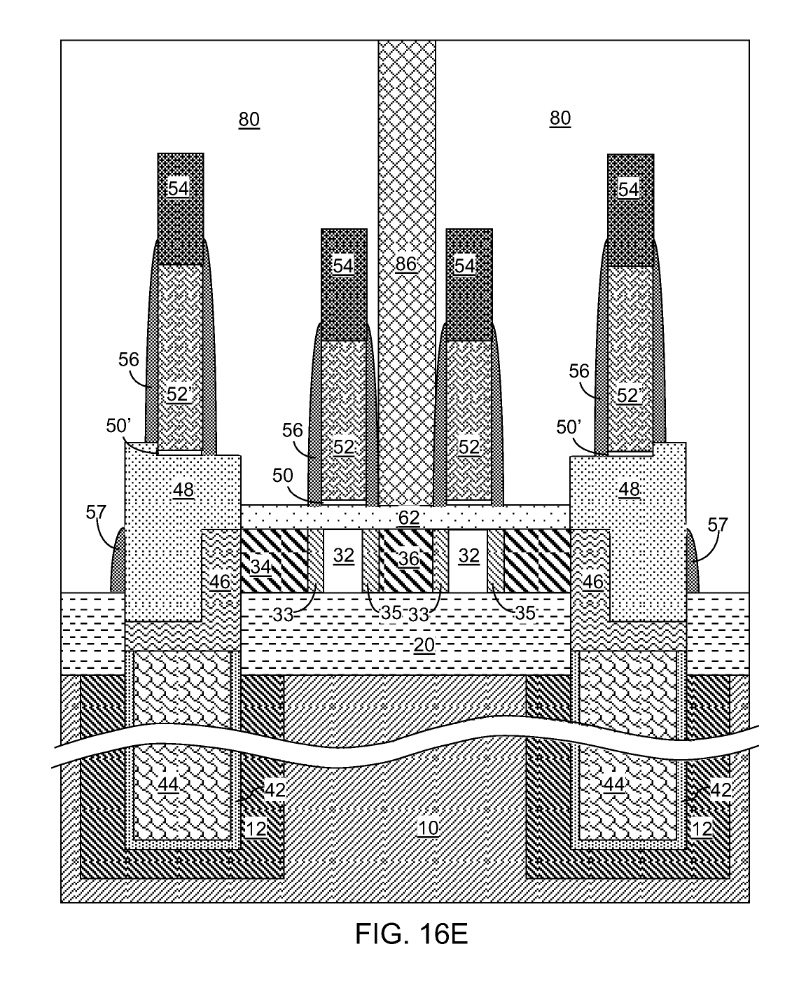

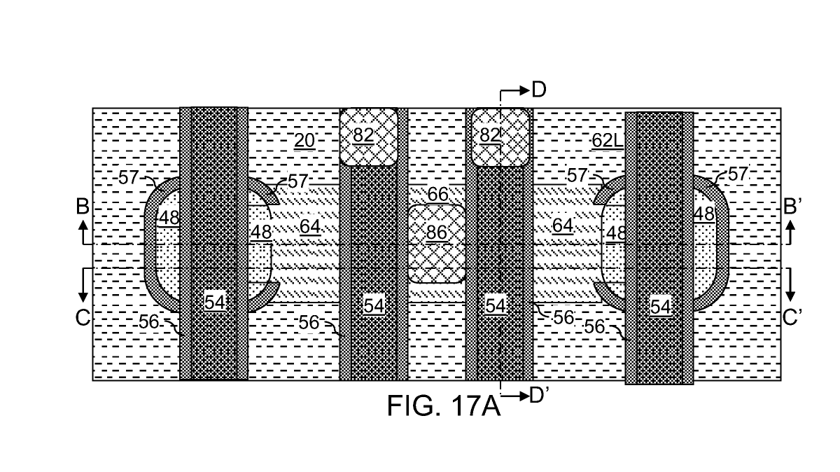

Further, for each access transistor, the pair of channel regions 32 are parallel to each other, and is laterally spaced from each other along a direction (e.g., a horizontal direction within plane D-D′) that is perpendicular to a direction (e.g., a horizontal direction within plane B-B′) connecting the geometrical center of the conductive strap structure 48 and a geometrical center of the pair of channel regions 32. The geometrical center of a conductive strap structure is illustrated by the end point of a vector W in FIG. 16B, and the geometrical center of a pair of channel regions 32 is represented by the starting point of the vector W in FIG. 16A. It is noted that the Cartesian coordinate of the geometrical center of an element occupying a volume can be given by (Xc, Yc, Zc), wherein

$$Xc = \frac{\int x d V}{\int d V} , \\ Yc = \frac{\int y d V}{\int d V} , and$$

$$Zc = \frac{\int z d V}{\int d V} ,$$

in which each integration is performed over all volume elements dV within the entire volume of the element.

Each gate dielectric 50 overlies a pair of channel regions 32, and laterally contacts sidewalls of a pair of channel regions 32. Each gate electrode 52 contacts top surfaces and sidewall surfaces of a gate dielectric 50.

Referring to FIGS. 16A-16D, a contact-level dielectric layer 80 and various contact via structures can be subsequently formed. The contact-level dielectric layer 80 includes a dielectric material such as silicon oxide, silicon nitride, organosilicate glass (OSG), or any other dielectric material that can be employed to form metal interconnect structures as known in the art. The various contact via structures can include, for example, gate contact via structures 82 that contact the gate electrode 50 or the passing gate electrode 50′, and a drain contact via structure 86 that contact the drain region 36. Optionally, metal semiconductor alloy regions (not shown) such as metal silicide portions can be formed between the drain region 36 and the drain contact via structure 86 and/or between the active and/or passing gate electrodes (52, 52′) and the gate contact via structures 82.

The structure illustrated in FIGS. 16A-16D includes a trigate fin field effect transistor (finFET) as the access transistor. A dual gate finFET can also be employed as the access transistor in lieu of the trigate finFET, for example, by not completely removing the lower pad portion 62 at the processing step of FIGS. 13A-13D, to provide a first variation of the exemplary semiconductor structure as illustrated in FIG. 16F.

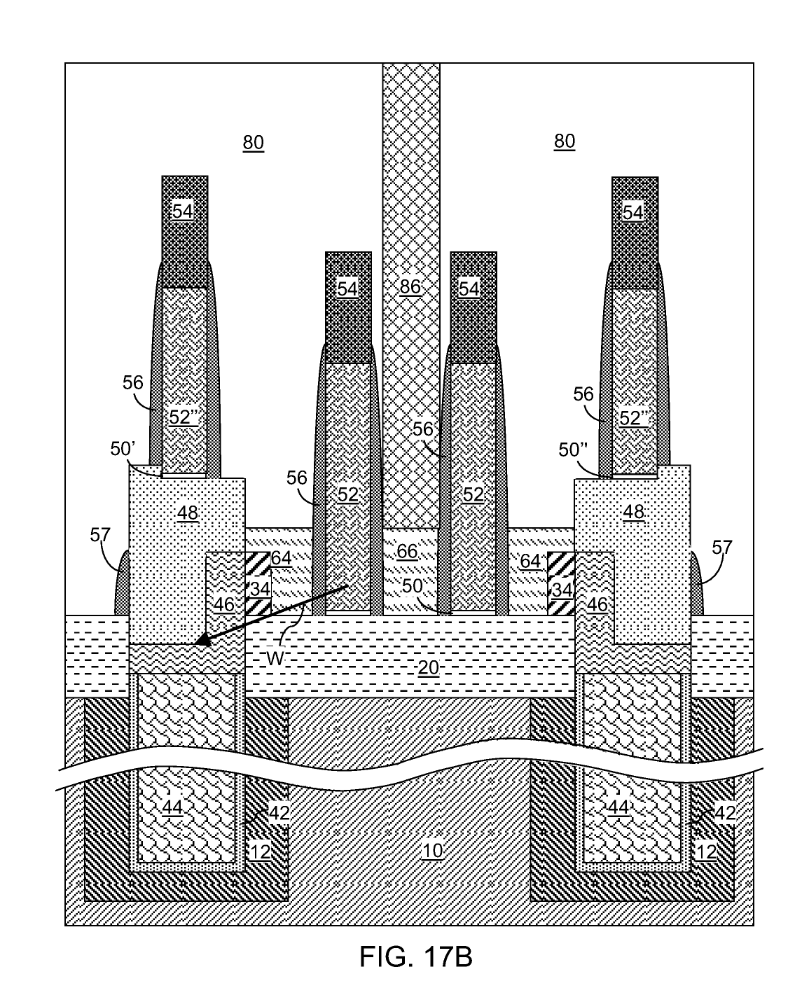

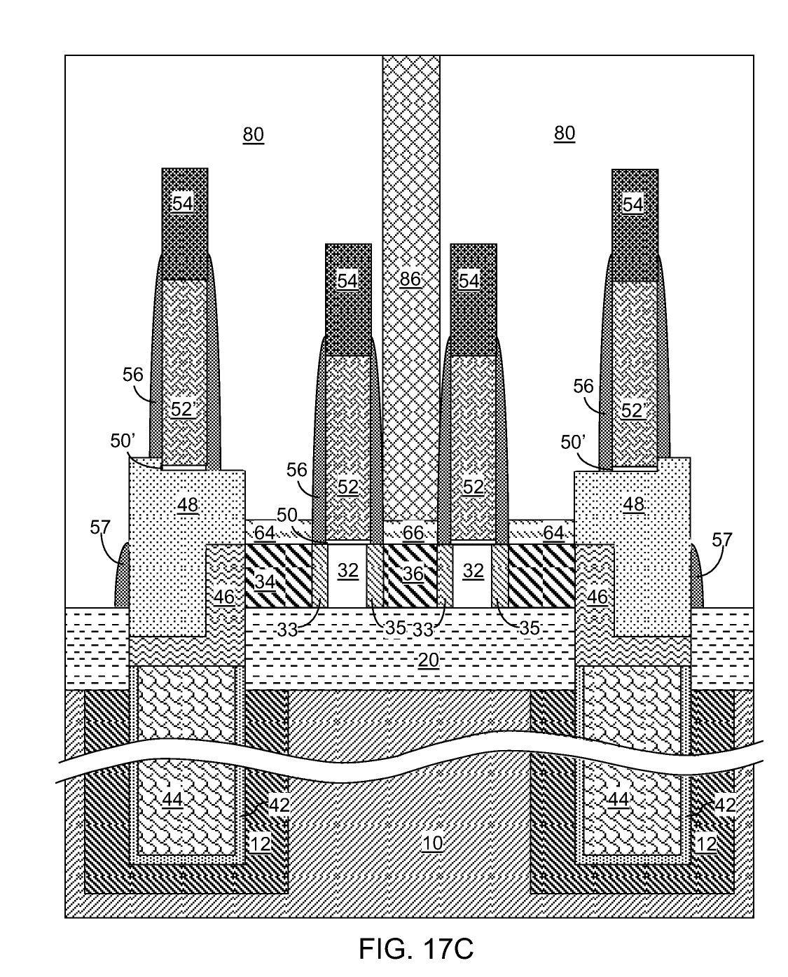

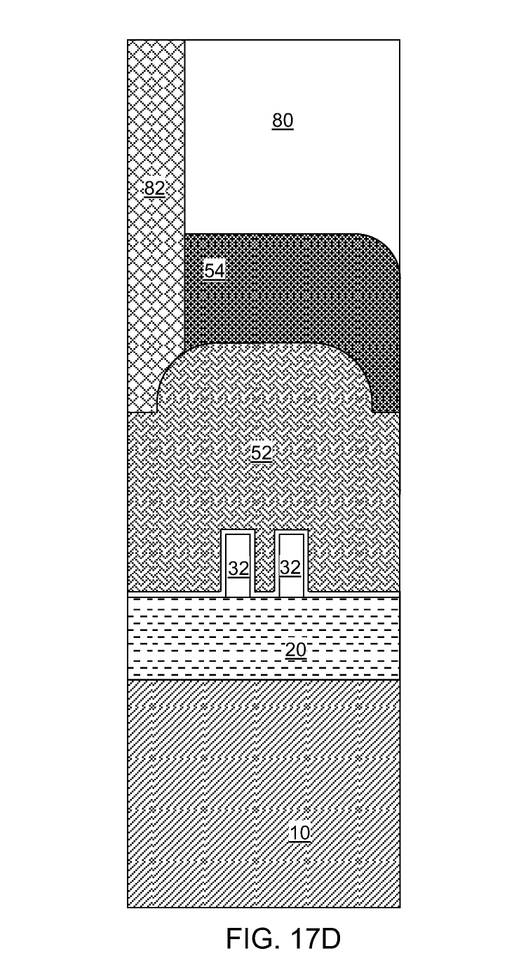

Referring to FIGS. 17A-17D, a second variation of the exemplary semiconductor structure is derived from the exemplary semiconductor structure of FIGS. 15A-15D by performing selective epitaxy to form epitaxially expanded source regions 64 and an epitaxially expanded drain region 66. The selective epitaxy deposits a doped semiconductor material directly on the semiconductor surfaces, i.e., on the physically exposed surfaces of the source regions 34 and the drain regions 36, while not depositing any semiconductor material on dielectric surfaces. Dopants of the same conductivity type as the dopants in the source region 34 and the drain region 36 are incorporated into the epitaxially expanded source region 64 and the epitaxially expanded drain region 66. The two linear portions of the semiconductor fin (34, 33, 32, 35, 36) become merged as the two epitaxially expanded source regions 64 and the epitaxially expanded drain region 66 fill the space between the two linear portions of the semiconductor fin (34, 33, 32, 35, 36). The epitaxially expanded drain region 66 contacts the two drain regions 66, and electrically shorts the two drain regions 66.

The epitaxially expanded source regions 64 and the epitaxially expanded drain region 66 can include the same material as, or a different semiconductor material from, the semiconductor material of the source region 34 and the drain region 36. Further, the epitaxially expanded source regions 64 and the epitaxially expanded drain region 66 can include the same dopant concentration as, or a different dopant concentration from, the dopant concentration of the source region 34 and the drain region 36. The thickness of the epitaxially expanded source regions 64 and the epitaxially expanded drain region 66, as measured from above the topmost surface of the source region 34 or the drain region 36, can be from 5 nm to 100 nm, although lesser and greater thicknesses can also be employed.

The semiconductor fin incorporates the epitaxially expanded source regions 64 and the epitaxially expanded drain region 66 during the selective epitaxy process. Upon completion of selective epitaxy, the semiconductor fin (34, 33, 32, 35, 36, 64, 66) includes the epitaxially-expanded source regions 64 contacting the source regions 34, and the epitaxially-expanded drain region 66 contacting, and electrically shorting, the two drain region 36.

In one embodiment, a sidewall of a source region 34 laterally contacting a conductive strap structure 46 can have a concave portion having a curvature, which corresponds to the convex portion of the sidewall of the conductive strap structure 46 in contact with the source region 34.

A contact-level dielectric layer 80 and various contact via structures can be subsequently formed. The various contact via structures can include, for example, gate contact via structures 82 that contact the gate electrode 50 or the passing gate electrode 50′, and a drain contact via structure 86 that contact the epitaxially expanded drain region 66. Optionally, metal semiconductor alloy regions (not shown) such as metal silicide portions can be formed between the epitaxially expanded drain region 66 and the drain contact via structure 86 and/or between the active and/or passing gate electrodes (52, 52′) and the gate contact via structures 82.

The structure illustrated in FIGS. 17A-17D includes a trigate fin field effect transistor (finFET) as the access transistor. A dual gate finFET can also be employed as the access transistor in lieu of the trigate finFET, for example, by not completely removing the lower pad portion 62 at the processing step of FIGS. 13A-13D, to provide another variation of the exemplary semiconductor structure.

While the disclosure has been described in terms of specific embodiments, it is evident in view of the foregoing description that numerous alternatives, modifications and variations will be apparent to those skilled in the art. Each of the embodiments described herein can be implemented individually or in combination with any other embodiment unless expressly stated otherwise or clearly incompatible. Accordingly, the disclosure is intended to encompass all such alternatives, modifications and variations which fall within the scope and spirit of the disclosure and the following claims.

What is claimed is:

1. A method of forming a semiconductor structure comprising:
forming at least one pad layer over a semiconductor-on-insulator (SOI) substrate;
forming a trench capacitor comprising an inner electrode, a node dielectric, and an outer electrode in said SOI substrate;
forming a dielectric capacitor cap over said inner electrode;
forming a trough in one of said at least one pad layer, wherein said trough overlies a portion of a top semiconductor layer of said SOI substrate and a sidewall of said dielectric capacitor cap is physically exposed within said trough;
forming a fin-defining spacer on sidewalls of said one of said at least one pad layer and said sidewall of said dielectric capacitor cap within said trough; and
forming a semiconductor fin by transferring a pattern of said fin-defining spacer into said top semiconductor layer.

2. The method of claim 1, further comprising forming a conductive strap structure on said inner electrode, wherein said dielectric capacitor cap is formed on said conductive strap structure, and said semiconductor fin contacts said conductive strap structure upon formation of said semiconductor fin.

3. The method of claim 2, wherein said conductive strap structure comprises a metallic material or a doped semiconductor material.

4. The method of claim 1, wherein said forming of said fin-defining spacer and said forming of said semiconductor fin comprise forming each of said fin-defining spacer and said semiconductor fin as a structure that is topologically homeomorphic to a torus.

5. The method of claim 1, further comprising forming an access transistor that controls current flow into, and out of, said trench capacitor by forming a pair of channel regions in said semiconductor fin.

6. The method of claim 5, wherein said forming of said access transistor further comprises:
forming a gate dielectric that straddles over portions of said semiconductor fin that correspond to said pair of channel regions; and
forming a gate electrode that contacts said gate dielectric.

7. The method of claim 6, further comprising:
forming a conductive strap structure on said inner electrode, wherein said dielectric capacitor cap is formed on said conductive strap structure;
forming a passing gate dielectric comprising a same material as said gate dielectric on sidewalls of said dielectric capacitor cap; and
forming a passing gate electrode comprising a same material as said gate electrode over said dielectric capacitor cap and on said passing gate dielectric.

8. The method of claim 6, further comprising:
forming a gate spacer on sidewalls of said gate electrode; and
forming a source region and at least one drain region in said semiconductor fin by implanting dopants into portions of said semiconductor fin employing said gate electrode and said gate spacer as an implantation mask.

9. The method of claim 6, further comprising forming a contact via structure, wherein said contact that is in direct contact with said get electrode.

10. The method of claim 1, wherein forming of said at least one pad layer comprises forming a stack of a lower pad layer and an upper pad layer on said SOI substrate, and said forming of said dielectric capacitor cap comprises:
depositing a dielectric material over said conductive strap structure and within an opening in said stack; and
removing said dielectric material from above a top surface of said upper pad layer, wherein a remaining portion of said dielectric material constitutes said dielectric capacitor cap.

11. The method of claim 10, wherein said forming of said trough comprises:
applying a photoresist layer over said upper pad layer after formation of said dielectric capacitor cap;
patterning said photoresist layer with an opening overlying said portion of a top semiconductor layer and a portion of said dielectric capacitor cap; and
transferring a composite pattern of an intersection of said opening and an area of said upper pad layer into said upper pad layer to form said trough.

12. The method of claim 10, wherein said fin-defining spacer comprises a material that is different from said upper pad layer, said lower pad layer, and said dielectric capacitor cap.

13. The method of claim 12, further comprising removing said upper pad layer selective to said fin-defining spacer, wherein said transferring of said pattern of said fin-defining spacer into said top semiconductor layer comprises etching said lower pad layer and said top semiconductor layer employing said fin-defining spacer as an etch mask.

14. The method of claim 10, wherein said upper lower pad layer comprises a first dielectric material and said upper pad layer comprises a second dielectric material that is different from said first dielectric material.

15. The method of claim 14, wherein said first dielectric material comprises a dielectric metal oxide and said second dielectric material comprises a silicon nitride.

16. The method of claim 1, wherein said semiconductor-on-insulator substrate comprises a stack, from bottom to top, of a bottom semiconductor layer, a buried insulator layer, and a top semiconductor layer.

17. The method of claim 1, wherein said fin-defining spacer is a material selected from the group consisting of amorphous carbon, dielectric metal oxide, polysilicon, and metal.

18. The method of claim 1, further comprising removing said fin-defining spacer and said at least one pad layer by an etching process selective to said semiconductor fin.
